(19) United States
(12) Patent Application Publication
(10) Pub. No.: US 2026/0173281 A1
(43) Pub. Date: Jun. 18, 2026

(54) DISPLAY DEVICE, ELECTRONIC DEVICE INCLUDING THE SAME, AND METHOD FOR FABRICATING THE DISPLAY DEVICE

(71) Applicant: Samsung Display Co., LTD., Yongin-si (KR)

(72) Inventors: Cheol Min PARK, Yongin-si (KR); Seung Ho KIM, Yongin-si (KR); Jin Su NAM, Yongin-si (KR); Nam Soo KANG, Yongin-si (KR); Byeong Beom KIM, Yongin-si (KR); Tae Hee YOON, Yongin-si (KR); Hye Ryeon JO, Yongin-si (KR)

(21) Appl. No.: 19/384,206

(22) Filed: Nov. 10, 2025

(30) Foreign Application Priority Data
Dec. 13, 2024 (KR) 10-2024-0186290
Feb. 3, 2025 (KR) 10-2025-0012910
Jul. 3, 2025 (KR) 10-2025-0089357

(51) Int. Cl. H05K 5/02; H10K 59/12; H10K 59/80; H10K 102/00

(52) U.S. Cl. CPC H05K 5/0217; H10K 59/1201; H10K 59/80; H10K 2102/311

(57) ABSTRACT

A display device includes a display panel including folding and non-folding areas, and a panel support member placed on the display panel and including a folding portion in the folding area and a non-folding portion in the non-folding area. The folding portion includes a grid pattern in which slits and bars are arranged alternately. The panel support member includes a first surface next to the display panel, a second surface opposed to the first surface, a first inner surface connected to the first surface in the slit, disposed between the first surface and the second surface and including a curved surface, and a second inner surface between the first inner surface and the second surface in the slit. A first angle defined by a first tangent touching the first inner surface and the first surface ranges from 15 degrees to 30 degrees when the first vertical distance is 0.5 micrometers.

This application claims priority to Korean Patent Application No. 10-2024-0186290, filed on Dec. 13, 2024, Korean Patent Application No. 10-2025-0012910, filed on Feb. 3, 2025, and Korean Patent Application No. 10-2025-0089357, filed on Jul. 3, 2025, and all the benefits accruing therefrom under 35 U.S.C. § 119, the contents of which in their entirety are herein incorporated by reference.

### BACKGROUND

### 1. Field

The disclosure relates to a display device, an electronic device including the same, and a method for fabricating a display device.

### 2. Description of the Related Art

As the information-oriented society evolves, various demands for display devices are ever increasing. Display devices may be a liquid-crystal display device, a field emission display device, a light-emitting display device, or the like. Light-emitting display devices may include an organic light-emitting display device including organic light-emitting diodes as light-emitting elements, an inorganic light-emitting display device including inorganic light-emitting diodes as light-emitting elements, etc.

Recently, in order to increase portability of the display device and provide a wider display screen, a bendable display device in which the display area may be bent, or a foldable display device in which the display area may be folded is being released.

### SUMMARY

Features of the disclosure provide a display device with improved flexibility and durability, an electronic device including the same, and a method for fabricating a display device.

It should be noted that features of the disclosure are not limited to the above-mentioned feature; and other features of the disclosure will be apparent to those skilled in the art from the following descriptions.

In an embodiment of the disclosure, a display device includes a display panel including a folding area and a non-folding area, and a panel support member placed on the display panel and including a folding portion disposed in the folding area and a non-folding portion disposed in the non-folding area, where the folding portion includes a grid pattern in which a plurality of slits and a plurality of bars are arranged alternately, where the panel support member includes, in a cross-section cut in a thickness direction, a first surface next (adjacent) to the display panel, a second surface opposed to the first surface, a first inner surface connected to the first surface in a slit of the plurality of slits, disposed between the first surface and the second surface and including a curved surface, and a second inner surface disposed between the first inner surface and the second surface in the slit, where a point where the first surface and the first inner surface meet is defined as a first point, a point where the second surface and the second inner surface meet is defined as a second point, and a point where the first inner surface and the second inner surface meet is defined as a third point, where the slit has a first width in a direction parallel to the first surface at the first point, a second width in a direction parallel to the second surface at the second point, and a third width, which is a minimum width, in the direction parallel to at least one of the first surface and the second surface at the third point, where the third width is smaller than the first width, and the first width is smaller than the second width, where a first reference point is defined where a straight line extended in a horizontal direction perpendicular to the thickness direction at a point distant from the first point by a first vertical distance in the thickness direction meets the first inner surface, and where a first angle defined by a first tangent touching the first inner surface at the first reference point and the first surface ranges from 15 degrees to 30 degrees when the first vertical distance is 0.5 micrometer (m).

In an embodiment, a distance between the first reference point and the first point in the horizontal direction is defined as a first horizontal distance, and where the first horizontal distance is two to four times the first vertical distance.

In an embodiment, a second reference point is defined where a straight line extended in the horizontal direction at a point distant from the second point by a second vertical distance in the thickness direction meets the second inner surface, where a second angle defined by a second tangent touching the second inner surface at the second reference point and the second surface is greater than the first angle, and where the second vertical distance is equal to the first vertical distance.

In an embodiment, a first contact point disposed on the first inner surface and next (adjacent) to the first point, and a second contact point next (adjacent) to the third point are defined, where a distance between the first point and the first contact point on the first inner surface is equal to a distance between the third point and the second contact point on the first inner surface, and where a first radius of a first inscribed circle touching the first inner surface at the first contact point is larger than a second radius of a second inscribed circle touching the first inner surface at the second contact point.

In an embodiment, an arbitrary third contact point disposed on the second inner surface is defined, and where a third radius of a third inscribed circle touching the second inner surface at the third contact point is greater than the first radius and the second radius.

In an embodiment, a distance by which the third point is spaced apart from the first surface in the thickness direction is greater than 0.2 times and less than 0.4 times the thickness of the panel support member.

In an embodiment, the thickness of the panel support member ranges from 80 μm (μm) to 150 μm.

In an embodiment, the first width ranges from 20 μm to 80 μm, the second width ranges from 40 μm to 150 μm, and the third width ranges from 10 μm to 40 μm.

In an embodiment, the second inner surface includes a curved surface next (adjacent) to the first inner surface and a flat surface next (adjacent) to the second surface.

In an embodiment, the panel support member includes or consists of glass.

In an embodiment, the display device further includes a filling member including a first portion disposed in the slit, and a second portion overlapping the folding portion on the second surface.

In an embodiment, the filling member further includes: the filling member includes a third portion overlapping the non-folding portion on the second surface, and a fourth portion disposed on a side surface of the panel support member.

In an embodiment of the disclosure, a display device includes a display panel including a folding area and a non-folding area, and a panel support member placed on the display panel and including a folding portion disposed in the folding area and a non-folding portion disposed in the non-folding area, where the folding portion includes a grid pattern in which a plurality of slits and a plurality of bars are arranged alternately, where the panel support member includes, in a cross-section cut in a thickness direction, a first surface next (adjacent) to the display panel, a second surface opposed to the first surface, a first inner surface connected to the first surface in a slit of the plurality of slits, disposed between the first surface and the second surface and including a curved surface, and a second inner surface disposed between the first inner surface and the second surface in the slit, where a point where the first surface and the first inner surface meet is defined as a first point, a point where the second surface and the second inner surface meet is defined as a second point, and a point where the first inner surface and the second inner surface meet is defined as a third point, where the slit has a first width in a direction parallel to the first surface at the first point, a second width in a direction parallel to the second surface at the second point, and a third width, which is a minimum width, in the direction parallel to at least one of the first surface and the second surface at the third point, where the third width is smaller than the first width, and the first width is smaller than the second width, and where the panel support member has a shape optimization index Q of 0.35 or greater defined by the following equation:

$$Ω = 100 \cdot \frac{D}{w 1 ( w 1 - w 3 )} \qquad [ Equation l ]$$

where w1 denotes the first width, w3 denotes the third width, and D denotes the distance by which the third point is spaced apart from the first surface in the thickness direction.

In an embodiment, the w3 ranges from 10 μm to 40 μm, the w1 ranges from 20 μm to 80 μm, and the D ranges from 20 μm to 50 μm.

In an embodiment of the disclosure, a method for fabricating a display device, the method includes forming a sketch line by irradiating a glass plate with a laser, bringing a first etchant into contact with at least a surface of the glass plate on which the sketch line is formed to define a slit along the sketch line, immersing the glass plate in which the slit is defined in a second etchant to perform first healing, chemically strengthening the glass plate after the first healing by immersing it in molten salt, immersing the chemically strengthened glass plate in a third etchant to perform second healing, and filling the slit of the glass plate after the second healing with a resin.

In an embodiment, an etching rate of the glass plate by the second etchant is slower than an etching rate of the glass plate by the first etchant.

In an embodiment, the second etchant and the third etchant include or consist of a same material as each other.

In an embodiment, the first etchant and the second etchant each include or consist of ammonium ions and bifluoride ions, where a ratio of ammonium ions to total ions in the first etchant is smaller than a ratio of ammonium ions to total ions in the second etchant, and where a ratio of bifluoride ions to total ions in the first etchant is larger than a ratio of bifluoride ions to total ions in the second etchant.

In an embodiment, the slit includes a first portion next (adjacent) to an upper surface of the glass plate, a second portion next (adjacent) to a lower surface of the glass plate, and a third portion between the first portion and the second portion in a thickness direction of the glass plate, and where a width of the third portion is smaller than a width of the first portion, and the width of the first portion is smaller than a width of the second portion.

In an embodiment of the disclosure, an electronic device includes a display device for displaying an image, a processor for providing an image driving signal to the display device, and a power module for supplying power to the display device and the processor, where the display device includes: a display panel including a folding area and a non-folding area; and a panel support member placed on the display panel and including a folding portion disposed in the folding area and a non-folding portion disposed in the non-folding area, where the folding portion includes a grid pattern in which a plurality of slits and a plurality of bars are arranged alternately, where the panel support member includes, in a cross-section cut in a thickness direction, a first surface next (adjacent) to the display panel, a second surface opposed to the first surface, a first inner surface connected to the first surface in a slit of the plurality of slits, disposed between the first surface and the second surface and including a curved surface, and a second inner surface disposed between the first inner surface and the second surface in the slit, where a point where the first surface and the first inner surface meet is defined as a first point, a point where the second surface and the second inner surface meet is defined as a second point, and a point where the first inner surface and the second inner surface meet is defined as a third point, where the slit has a first width in a direction parallel to the first surface at the first point, a second width in a direction parallel to the second surface at the second point, and a third width, which is a minimum width, in the direction parallel to at least one of the first surface and the second surface at the third point, where the third width is smaller than the first width, and the first width is smaller than the second width, where a first reference point is defined where a straight line extended in a horizontal direction perpendicular to the thickness direction at a point distant from the first point by a first vertical distance in the thickness direction meets the first inner surface, and where a first angle defined by a first tangent touching the first inner surface at the first reference point and the first surface ranges from 15 degrees to 30 degrees when the first vertical distance is 0.5 μm.

In an embodiment of the disclosure, the flexibility and durability of a display device may be improved.

It should be noted that effects of the disclosure are not limited to those described above and other effects of the disclosure will be apparent to those skilled in the art from the following descriptions.

### BRIEF DESCRIPTION OF THE DRAWINGS

The above and other advantages and features of the disclosure will become more apparent by describing in detail embodiments thereof with reference to the attached drawings, in which:

FIG. 1 is a perspective view showing an embodiment of a display device of the disclosure when it is unfolded.

FIG. 2 is a perspective view showing the embodiment of the display device when it is folded.

FIG. 3 is a perspective view showing another embodiment of a display device of the disclosure when it is unfolded.

FIG. 4 is a perspective view showing the embodiment the display device of the disclosure when it is folded.

FIG. 5 is a cross-sectional view showing an embodiment of a display device of the disclosure.

FIG. 6 is a cross-sectional view showing embodiments of another embodiment of a display device of the disclosure.

FIG. 7 is a cross-sectional view showing an embodiment of a display panel of the disclosure.

FIG. 8 is a plan view of embodiments of a panel support member of the disclosure.

FIG. 9 is a cross-sectional view taken along line X1-X1′ in FIG. 8.

FIG. 10 is an enlarged view of area A of FIG. 9.

FIG. 11 and FIG. 12 are enlarged views of area AA of FIG. 10.

FIG. 13 is an enlarged view of area AB of FIG. 10.

FIG. 14 is an enlarged view showing another embodiment of area A of a panel support member.

FIG. 15 is a cross-sectional view showing embodiments of a ball drop test conducted on the stack structure of a display panel and a panel support member.

FIG. 16 is a flowchart for illustrating embodiments of a method for fabricating a display device of the disclosure.

FIG. 17 is a cross-sectional view showing operation S100 of FIG. 16.

FIG. 18 and FIG. 19 are cross-sectional views showing operation S200 of FIG. 16.

FIG. 20 is a cross-sectional view showing operation S300 of FIG. 16.

FIG. 21 is a cross-sectional view showing operation S400 of FIG. 16.

FIG. 22 is a cross-sectional view showing operation S500 of FIG. 16.

FIGS. 23 to 26 are cross-sectional views showing operation S600 of FIG. 16.

FIG. 27 is a block diagram of an embodiment of an electronic device of the disclosure.

FIG. 28 is a view showing electronic devices according to a variety of embodiments of the disclosure.

### DETAILED DESCRIPTION

The disclosure will now be described more fully hereinafter with reference to the accompanying drawings, in which preferred embodiments of the disclosure are shown. This disclosure may, however, be embodied in different forms and should not be construed as limited to the embodiments set forth herein. Rather, these embodiments are provided so that this disclosure will be thorough and complete, and will filly convey the scope of the disclosure to those skilled in the art.

It will also be understood that when a layer is referred to as being “on” another layer or substrate, it may be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

Each of the features of the embodiments of the disclosure may be combined or combined with each other, in part or in whole, and technically various interlocking and driving are possible. Each embodiment may be implemented independently of each other or may be implemented together in an association.

Hereinafter, embodiments of the disclosure will be described in detail with reference to the accompanying drawings.

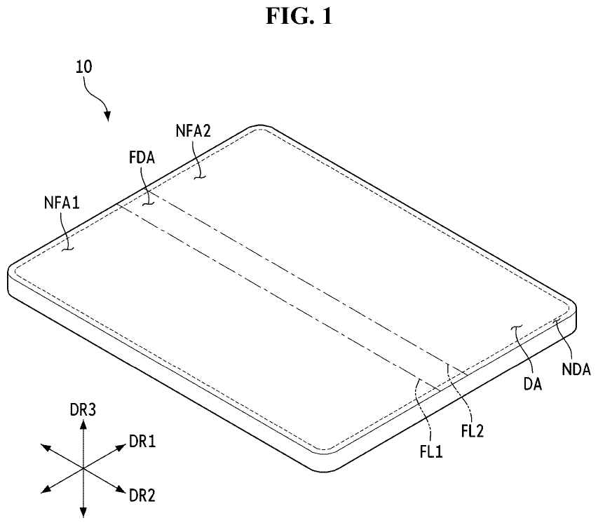

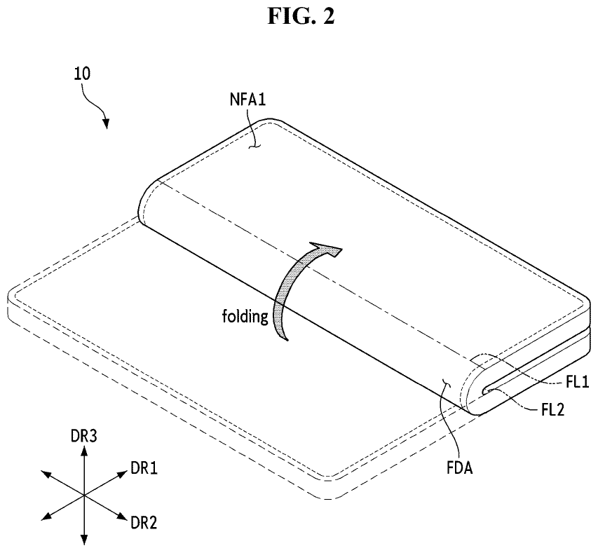

FIG. 1 is a perspective view showing an embodiment of a display device of the disclosure when it is unfolded. FIG. 2 is a perspective view showing the display device in the embodiment of the disclosure when it is folded.

Referring to FIGS. 1 and 2, FIG. 1 shows a first state in which the display device 10 is unfolded without being folded over the folding lines FL1 and FL2, and FIG. 2 shows a second state in which the display device 10 is folded over the folding lines FL1 and FL2.

A display device 10 in the embodiment of the disclosure is for displaying moving images or still images. The display device 1 may be used as the display screen of portable electronic devices such as a mobile phone, a smart phone, a tablet personal computer (“PC”), a smart watch, a watch phone, a mobile communications terminal, an electronic notebook, an electronic book, a portable multimedia player (“PMP”), a navigation device and a ultra mobile PC (“UMPC”), as well as the display screen of various products such as a television, a notebook, a monitor, a billboard and the Internet of Things.

In the drawings, the first direction DR1 and the second direction DR2 intersect each other as the horizontal directions. In an embodiment, the first direction DR1 and the second direction DR2 may be perpendicular to each other, for example. In addition, a third direction DR3 may intersect the first direction DR1 and the second direction DR2, and may be a vertical direction, for example. Herein, the side indicated by the arrow of each of the first to third directions DR1, DR2 and DR3 may be also referred to as a first side, while the opposite side may be also referred to as a second side unless specifically state otherwise. As used herein, the terms “on,” “upper side,” “above,” “top” and “upper surface” refer to the side indicated by the arrow of the third direction DR3 as shown in the drawings. The terms “under,” “lower side,” “below,” “bottom” and “lower surface” refer to the opposite side indicated by the arrow of the third direction DR3 as shown in the drawings.

In the drawings, the first direction DR1 may refer to a direction parallel to a side of the display device 10, e.g., the horizontal direction of the display device 10 when viewed from the top. A second direction DR2 may refer to a direction parallel to another side of the display device 10 that meet the side of the display device 10, e.g., the vertical direction of the display device 10 when viewed from the top. A third direction DR3 may refer to the thickness direction of the display device 10.

The display device 10 may have a quadrangular shape, such as a quadrangular shape, e.g., rectangular shape when viewed from the top. Each of the corners of the display device 10 may define a right angle or may be rounded when viewed from the top. The front surface of the display device 10 may include two shorter sides extended in the first direction DR1 and two longer sides extended in the second direction DR2.

The display device 10 may include the display area DA and a non-display area NDA. The shape of the display area DA may follow the shape of the display device 10 when viewed from the top. In an embodiment, when the display device 10 has a quadrangular shape, e.g., rectangular shape when viewed from the top, the display area DA may also have a quadrangular shape, e.g., rectangular shape when viewed from the top, for example.

The display area DA may include a plurality of pixels to display images. The non-display area NDA may not include pixels and thus may not display images. The non-display area NDA may be disposed around the display area DA. The non-display area NDA may surround the display area DA, but the embodiments of the disclosure are not limited thereto. The display area DA may be partially surrounded by the non-display area NDA.

The display device 10 may stay either in a first state when it is unfolded or a second state when it is folded. In an embodiment of the disclosure, the display device 10 may be folded inward so that a portion of the display device DA faces a remaining (the other) part (in-folding manner), as shown in FIG. 2. In this instance, a portion of the front surface of the display device 10 may face a remaining (the other) part when it is folded. In another embodiment, the display device 10 may be folded outward (out-folding manner) such that a portion of the rear surface faces a remaining (the other) part when it is folded.

The display device 10 may include a folding area FDA, a first non-folding area NFA1, and a second non-folding area NFA2. The display device 10 may be bent or folded at the folding area FDA, while it cannot be bent or folded at the first non-folding area NFA1 and the second non-folding area NFA2. In an embodiment of the disclosure, the first non-folding area NFA1 and the second non-folding area NFA2 may be flat areas of the display device 10.

The first non-folding area NFA1 may be disposed on one side, e.g., the left side of the folding area FDA. The second non-folding area NFA2 may be disposed on the opposite side, e.g., the right side of the folding area FDA. The folding area FDA may be defined by the first folding line FL1 and the second folding line FL2, where the display device 10 may be bent with a predetermined curvature. The first folding line FL1 may be the boundary between the folding area FDA and the first non-folding area NFA1, and the second folding line FL2 may be the boundary between the folding area FDA and the second non-folding area NFA2.

The first folding line FL1 and the second folding line FL2 may be extended in the second direction DR2 as shown in FIGS. 1 and 2, and the display device 10 may be folded over the second direction DR2. Accordingly, the length of the display device 10 in the first direction DR1 may be reduced to about half, so that the display device 10 is easy to carry.

The first non-folding area NFA1 may be disposed on one side, e.g., the left side of the folding area FDA. The second non-folding area NFA2 may be disposed on the opposite side, e.g., the right side of the folding area FDA. Herein, the left side may refer to a side in the first direction DR1, and the right side may refer to the opposite side in the first direction DR1.

When the first folding line FL1 and the second folding line FL2 are extended in the second direction DR2 as shown in FIGS. 1 and 2, the length of the folding area FDA in the second direction DR2 may be larger than the length in the first direction DR1. In addition, the length of the first non-folding area NFA1 in the second direction DR2 may be larger than the length of the first non-folding area NFA1 in the first direction DR1. The length of the second non-folding area NFA2 in the second direction DR2 may be larger than the length of the second non-folding area NFA2 in the first direction DR1.

Each of the display area DA and the non-display area NDA may overlap at least one of the folding area FDA, the first non-folding area NFA1, and the second non-folding area NFA2. In the example shown in FIGS. 1 and 2, each of the display area DA and the non-display area NDA overlaps the folding area FDA, the first non-folding area NFA1 and the second non-folding area NFA2.

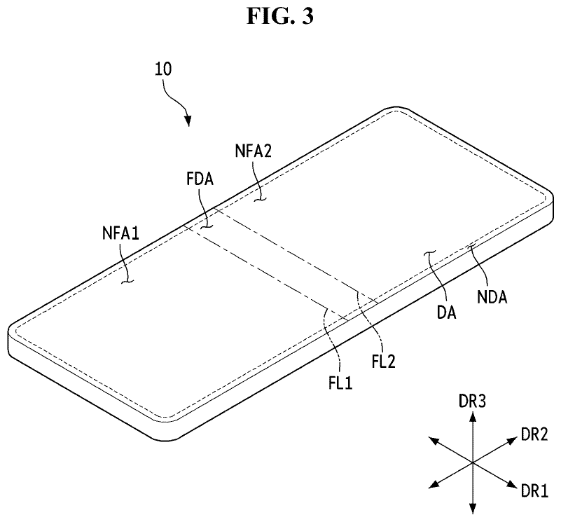

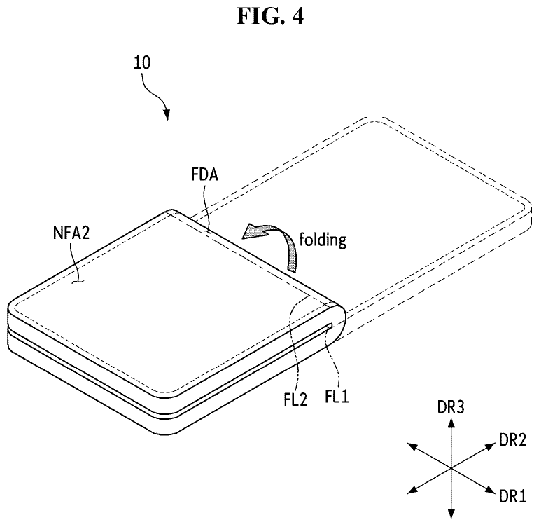

FIG. 3 is a perspective view showing another embodiment of a display device of the disclosure when it is unfolded. FIG. 4 is a perspective view showing the display device in the embodiment of the disclosure when it is folded.

Referring to FIGS. 3 and 4 in conjunction with FIGS. 1 and 2, FIG. 3 shows a first state in which the display device 10 is unfolded without being folded over the folding lines FL1 and FL2, and FIG. 4 shows a second state in which the display device 10 is folded over the folding lines FL1 and FL2.

The embodiment of FIGS. 3 and 4 is substantially identical to the embodiment of FIGS. 1 and 2 except that a first folding line FL1 and a second folding line FL2 are extended in the first direction DR1 and a display device 10 may be folded in the second direction DR2, so that the length of the display device 10 in the second direction DR2 may be reduced by approximately half Therefore, the elements of FIGS. 3 and 4 identical to those of FIGS. 1 and 2 will not be described to avoid redundancy.

In the first state in which the display device 10 is unfolded, the longer sides of the display device 10 may be extended in the second direction DR2, and the shorter sides of the display device 10 may be extended in the first direction DR1.

The first folding line FL1 and the second folding line FL2 may be extended in the first direction DR1 as shown in FIGS. 3 and 4, and the display device 10 may be folded over the first direction DR1.

The first non-folding area NFA1 may be disposed on one side, e.g., the lower side of the folding area FDA. The second non-folding area NFA2 may be disposed on the opposite side, e.g., the upper side of the folding area FDA. Herein, the upper side may refer to a side in the second direction DR2, and the lower side may refer to the opposite side in the second direction DR2.

When the first folding line FL1 and the second folding line FL2 are extended in the first direction DR1 as shown in FIGS. 3 and 4, the length of the folding area FDA in the first direction DR1 may be larger than the length in the second direction DR2. In addition, the length of the first non-folding area NFA1 in the second direction DR2 may be larger than the length of the first non-folding area NFA1 in the first direction DR1. The length of the second non-folding area NFA2 in the second direction DR2 may be larger than the length of the second non-folding area NFA2 in the first direction DR1.

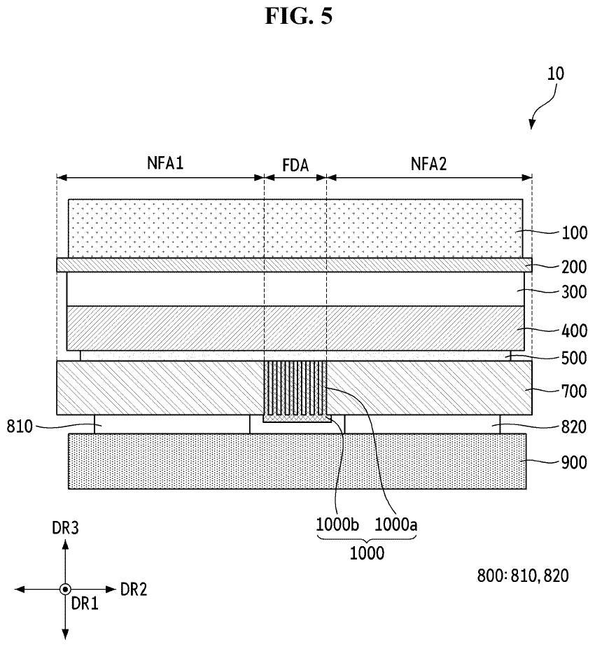

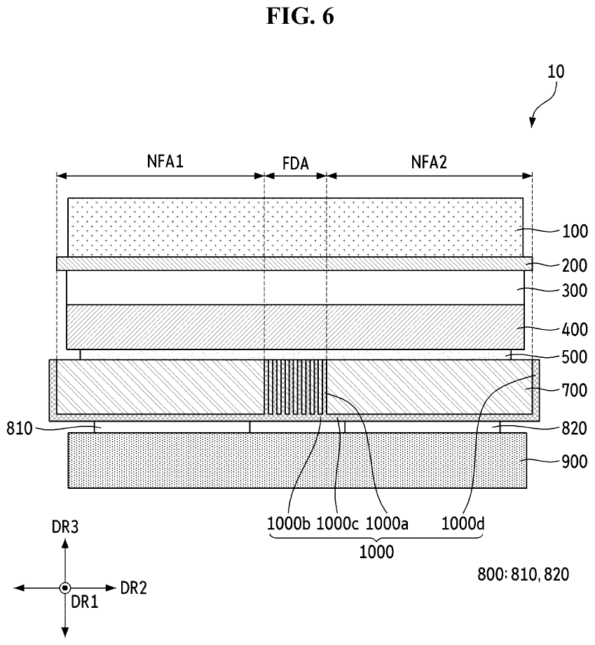

FIG. 5 is a cross-sectional view showing an embodiment of a display device of the disclosure. FIG. 6 is a cross-sectional view showing another embodiment of a display device of the disclosure.

Referring to FIGS. 5 and 6, the display device 10 may include an upper protective member 100, a window member 200, a first adhesive member 300, a display panel 400, a second adhesive member 500, a panel support member 700, a third adhesive member 800, a lower functional member 900, and a filling member 1000.

The display panel 400 may be a panel for displaying images. The display panel 400 may be an organic light-emitting display panel including an organic light-emitting layer, a quantum-dot light-emitting display panel including a quantum-dot light-emitting layer, an inorganic light-emitting display panel using inorganic semiconductor elements as the light-emitting elements, and a micro light-emitting display panel using micro light-emitting diodes as the light-emitting elements. In the following description, an organic light-emitting display panel is employed as the display panel 400. It is, however, to be understood that the disclosure is not limited thereto.

The window member 200 may be attached to the front surface of the display panel 400 by the first adhesive member 300. The window member 200 is including or consisting of a transparent material, and may be glass or plastic, for example. In an embodiment, the window member 200 may be an ultra thin glass (“UTG”) having a thickness of 0.1 millimeter (mm) or less or a transparent polyimide film, for example.

The first adhesive member 300 may be disposed on the rear surface of the window member 200. In an embodiment, the first adhesive member 300 may be disposed between the window member 200 and the display panel 400, for example. The window member 200 and the display panel 400 may be coupled with each other by the first adhesive member 300. The first adhesive member 300 may include an adhesive material such as a pressure sensitive adhesive (“PSA”) and an optically clear adhesive (“OCA”). The first adhesive member 300 may include an acrylic adhesive material.

The upper protective member 100 may be disposed on the front surface of the window member 200. The upper protective member 100 may be attached on the front surface of the window member 200. The upper protective member 100 may perform at least one of functions of anti-scattering when the window member 200 is broken, shock absorption, anti-scratch, anti-fingerprint, and anti-glare.

In an embodiment, a light-blocking pattern may be formed on the rear surface of the upper protective member 100. The light-blocking pattern may be disposed at or next (adjacent) to the edge of the upper protective member 100. The light-blocking pattern may include a light-blocking material that may block light. In an embodiment, the light-blocking pattern may be an inorganic black pigment such as carbon black, organic black pigment, or an opaque metallic substance, for example.

Although not shown in the drawings, a cover window may be further disposed on the upper protective member 100. The cover window may be a protective film for protecting the display device 10 from external shock. The cover window may be attached to the display device 10 or removed from the display device 10 through an adhesive member. In other words, the cover window may be a changeable window. In an embodiment of the disclosure, the cover window may include, but is not limited to, at least one of flexible polyethylene terephthalate (“PET”) and thermoplastic polyurethane (“TPU”).

The panel support member 700 may be disposed on the rear surface of the display panel 400. The panel support member 700 may be a rigid member that does not easily change shape or volume due to external pressure. Since the panel support member 700 is a rigid member that does not easily change shape or volume due to external pressure, it may support the display panel 400.

In an embodiment, the panel support member 700 may include a glass material. In an embodiment, the panel support member 700 may include an ultra-thin glass (“UTG”) having a thickness of 300 micrometers (m) or less, for example. Preferably, the thickness of the panel support member 700 may be approximately 80 μm to 150 μm.

The panel support member 700 may include aluminosilicate glass or soda-lime glass for performing a chemical strengthening process performed in a method S1 for fabricating a display device described below. In an embodiment of the disclosure, when the panel support member 700 includes aluminosilicate glass, the panel support member 700 may include or consist of approximately 60% to 65% silicon dioxide (SiO2), approximately 15% to 20% aluminum oxide (Al2O3), approximately 10% to 15% sodium oxide (Na₂O), and approximately 2% to 5% magnesium oxide (MgO). In another embodiment of the disclosure, when the panel support member 700 includes soda-lime glass, the panel support member 700 may include or consist of approximately 65% to 70% silicon dioxide (SiO2), approximately 3% to 5% aluminum oxide (Al2O3), approximately 10% to 15% sodium oxide (Na₂O), and approximately 5% to 10% magnesium oxide (MgO).

The panel support member 700 may include a lattice pattern disposed on the folding area FDA so that it may be easily bent in the folding area FDA. As the panel support member 700 includes the lattice pattern disposed in the folding area FDA, the panel support member 700 may be easily bent when the display device 10 is folded.

The second adhesive member 500 may be disposed on the rear surface of the display panel 400. In an embodiment, the first adhesive member 300 may be disposed between the panel support member 700 and the display panel 400, for example. The panel support member 700 and the display panel 400 may be coupled with each other by the second adhesive member 500. The second adhesive member 500 may include an adhesive material such as a pressure sensitive adhesive (“PSA”) and an optically clear adhesive (“OCA”). The second adhesive member 500 may include an acrylic adhesive material.

The filling member 1000 may be placed inside the grid pattern of the panel support member 700 and on the lower surface of the panel support member 700. Specifically, the filling member 1000 may be placed inside slits of the grid pattern of the panel support member 700 and between the lower functional member 900 and the panel support member 700. At least a portion of the filling member 1000 may be disposed in the same layer as the third adhesive member 800. At least a portion of the filling member 1000 may be disposed between the (3-1) adhesive member 810 and the (3-2) adhesive member 820.

The filling member 1000 may prevent particles from permeating into the grid pattern and damaging the display panel 400. The filling member 1000 may include a material having flexibility and elasticity to reduce the folding stress of the display device 10. In an embodiment, the filling member 1000 may include a resin, for example.

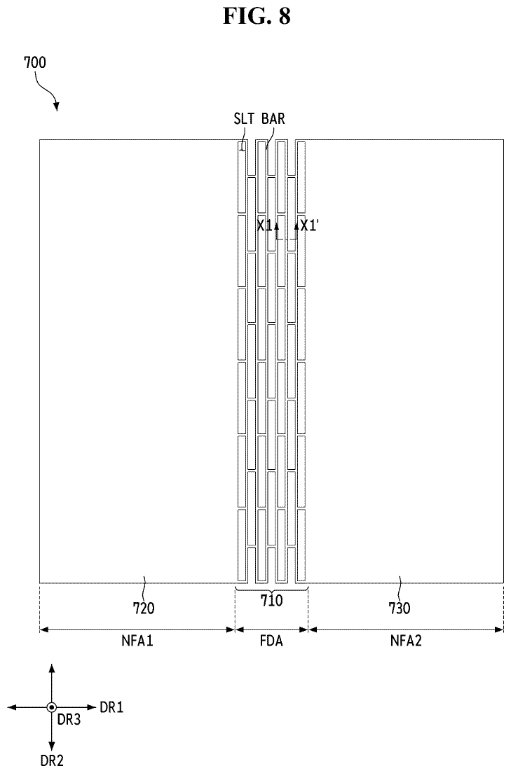

In an embodiment, as shown in FIG. 5, the filling member 1000 may include a first portion 1000a and a second portion 1000b. The first portion 1000a may be disposed inside the grid pattern of the panel support member 700, i.e., inside slits SLT (refer to FIG. 8) described below. The second portion 1000b may be placed on the first portion 1000a and may be disposed on the lower surface of the panel support member 700. The first portion 1000a and the second portion 1000b may be in line with the folding area FDA in the third direction DR3.

In another embodiment, as shown in FIG. 6, the filling member 1000 may further include a third portion 1000c and a fourth portion 1000d. The third portion 1000c may be disposed on one side and/or the opposite side of the second portion 1000b, and may be disposed in the non-folding area FDA. The fourth portion 1000d may be disposed on one side of the third portion 1000c, and may be disposed on a side surface of the panel support member 700.

In an embodiment of the disclosure, the thickness of the second portion 1000b and the third portion 1000c in the third direction DR3 may be, but is not limited to, approximately 5 μm to 40 μm.

Although the thickness (e.g., the length in the third direction DR3) of the second portion 1000b is smaller than the thickness (e.g., the length in the third direction DR3) of the third adhesive member 800 described later in the drawings, the disclosure is not limited thereto. In an embodiment, the thickness of the second portion 1000b may be equal to the thickness of the third adhesive member 800 described below. Accordingly, the second portion 1000b may be in direct contact with the lower functional member 900 and may support the grid pattern of the panel support member 700 to enhance the durability of the panel support member 700.

In another embodiment, a separate elastic member (not shown) may be further disposed between the second portion 1000b and the lower functional member 900. In this instance, the elastic member (not shown) may support a gap between the second portion 1000b and the lower functional member 900.

The lower functional member 900 may include one or more members to perform a variety of functions. In an embodiment, the lower functional member 900 may include at least one of: a light-blocking layer for absorbing light incident from outside; a buffer layer for absorbing external shock; and a heat dissipation layer for efficiently discharging heat from the display panel 400, for example. In addition, it may further include a digitizer member for sensing proximity or contact of an electronic pen such as a stylus pen supporting the electromagnetic resonance (“EMR”) technology. In addition, it may include a waterproof/dustproof member to prevent moisture or dust from permeating.

The third adhesive member 800 may be disposed on the rear surface of the panel support member 700. In an embodiment, the first adhesive member 300 may be disposed between the panel support member 700 and the lower functional member 900, for example. The panel support member 700 and the lower functional member 900 may be coupled with each other through the third adhesive member 800. The third adhesive member 800 may include an adhesive material such as a pressure sensitive adhesive (“PSA”) and an optically clear adhesive (“OCA”). The third adhesive member 800 may include an acrylic adhesive material.

The third adhesive member 800 may include a (3-1) adhesive member 810 in line with the first non-folding area NFA1, and a (3-2) adhesive member 820 in line with the second non-folding area NFA2.

In an embodiment, as shown in FIG. 5, the (3-1) adhesive member 810 and the (3-2) adhesive member 820 may be spaced apart from each other with the second portion 1000b of the filling member 1000 therebetween. In another embodiment, as shown in FIG. 6, the (3-1) adhesive member 810 and the (3-2) adhesive member 820 may each be in direct contact with the third portion 1000c of the filling member 1000.

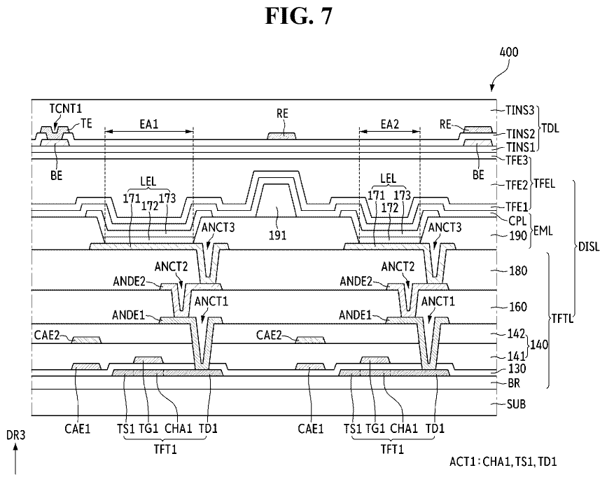

FIG. 7 is a cross-sectional view showing an embodiment of a display panel of the disclosure.

Referring to FIG. 7, the display panel 400 may include a substrate SUB, a display layer DISL disposed on the substrate SUB, and a touch detecting layer TDL disposed on the display layer DISL. The display layer DISL may include a thin-film transistor layer TFTL, an emission material layer EML, and an encapsulation layer TFEL.

The thin-film transistor layer TFTL may be disposed on the substrate SUB. The thin-film transistor layer TFTL may include a barrier layer BR, a thin-film transistor TFT1, a first capacitor electrode CAE1, a second capacitor electrode CAE2, a first anode connection electrode ANDE1, a second anode connection electrode ANDE2, a gate insulator 130, a first inter-dielectric layer 141, a second inter-dielectric layer 142, a first planarization layer 160, a second planarization layer 180.

The substrate SUB may include or consist of an insulating material such as a polymer resin. In an embodiment, the substrate SUB may include or consist of polyimide, for example. The substrate SUB may be a flexible substrate that may be bent, folded, or rolled.

The barrier layer BR may be disposed on the substrate SUB. The barrier layer BR is a film for protecting the thin-film transistors of the thin-film transistor layer TFTL and an emissive layer 172 of the emission material layer EML. The barrier layer BR may be made up of multiple inorganic films stacked on one another alternately. In an embodiment, the barrier layer BR may be made up of multiple layers in which one or more inorganic layers of a silicon nitride layer, a silicon oxynitride layer, a silicon oxide layer, a titanium oxide layer and an aluminum oxide layer are alternately stacked on one another, for example.

The thin-film transistor TFT1 may be placed on the barrier layer BR. An active layer ACT1 of the thin-film transistor TFT1 may be disposed on the barrier layer BR. The active layer ACT1 of the thin-film transistor TFT1 may include polycrystalline silicon, monocrystalline silicon, low-temperature polycrystalline silicon, amorphous silicon, or an oxide semiconductor.

The active layer ACT1 may include a channel region CHA1, a source region TS1 and a drain region TD1. The channel region CHA1 may overlap with a gate electrode TG1 in the third direction DR3 that is the thickness direction of the substrate SUB. The source region TS1 may be disposed on one side of the channel region CHA1, and the drain region TD1 may be disposed on the opposite side of the channel region CHA1. The source region TS1 and the drain region TD1 may not overlap with the gate electrode TG1 in the third direction DR3. The source region TS1 and the drain region TD1 may be formed by doping a silicon semiconductor or an oxide semiconductor with ions or impurities to have conductivity.

The gate insulator 130 may be placed on the active layer ACT1 of the thin-film transistor TFT1. The gate insulator 130 may include an inorganic layer, e.g., a silicon nitride layer, a silicon oxynitride layer, a silicon oxide layer, a titanium oxide layer, or an aluminum oxide layer.

The gate electrode TG1 of the thin-film transistor TFT1 and the first capacitor electrode CAE1 may be arranged on the gate insulator 130. The gate electrode TG1 may overlap with the channel region CHA1 in the third direction DR3. Although the gate electrode TG1 and the first capacitor electrode CAE1 are spaced apart from each other in the example shown in FIG. 7, the gate electrode TG1 and the first capacitor electrode CAE1 may be connected with each other as a single piece. The gate electrode TG1 and the first capacitor electrode CAE1 may be made up of a single layer or multiple layers of one of molybdenum (Mo), aluminum (Al), chromium (Cr), gold (Au), titanium (Ti), nickel (Ni), neodymium (Nd) and copper (Cu) or any alloys thereof.

The first inter-dielectric layer 141 may be disposed on the gate electrode TG1 of the thin-film transistor TFT1 and the first capacitor electrode CAE1. The first inter-dielectric layer 141 may include an inorganic layer, e.g., a silicon nitride layer, a silicon oxynitride layer, a silicon oxide layer, a titanium oxide layer, or an aluminum oxide layer. The first inter-dielectric layer 141 may be made up of multiple inorganic films.

The second capacitor electrode CAE2 may be disposed on the first inter-dielectric layer 141. The second capacitor electrode CAE2 may overlap the first capacitor electrode CAE1 of the thin-film transistor TFT1 in the third direction DR3. In addition, when the gate electrode TG1 and the first capacitor electrode CAE1 are formed as a single piece, the second capacitor electrode CAE2 may overlap the gate electrode TG1 in the third direction DR3. Since the first inter-dielectric layer 141 has a dielectric constant, a capacitor may be formed by the first capacitor electrode CAE1, the second capacitor electrode CAE2 and the first inter-dielectric layer 141 arranged therebetween. The second capacitor electrode CAE2 may be made up of a single layer or multiple layers of one of molybdenum (Mo), aluminum (Al), chromium (Cr), gold (Au), titanium (Ti), nickel (Ni), neodymium (Nd) and copper (Cu) or any alloys thereof.

A second inter-dielectric layer 142 may be disposed over the second capacitor electrode CAE2. The second inter-dielectric layer 142 may include an inorganic layer, e.g., a silicon nitride layer, a silicon oxynitride layer, a silicon oxide layer, a titanium oxide layer, or an aluminum oxide layer. The second inter-dielectric layer 142 may include or consist of a plurality of inorganic films.

A first anode connection electrode ANDE1 may be placed on the second inter-dielectric layer 142. The first anode connection electrode ANDE1 may be connected to the drain region TD1 of the thin-film transistor TFT1 through a first connection contact hole ANCT1 that penetrates the gate insulator 130, the first inter-dielectric layer 141 and the second inter-dielectric layer 142. The first anode connection electrode ANDE1 may be made up of a single layer or multiple layers of one of molybdenum (Mo), aluminum (Al), chromium (Cr), gold (Au), titanium (Ti), nickel (Ni), neodymium (Nd) and copper (Cu) or any alloys thereof.

A first planarization layer 160 may be placed over the first anode connection electrode ANDE1 for providing a flat surface over level differences due to the thin-film transistor TFT1. The first planarization layer 160 may include an organic layer such as an acryl resin, an epoxy resin, a phenolic resin, a polyamide resin and a polyimide resin.

A second anode connection electrode ANDE2 may be disposed on the first planarization layer 160. The second anode connection electrode ANDE2 may be connected to the first anode connection electrode ANDE1 through a second connection contact hole ANCT2 penetrating the first planarization layer 160. The second anode connection electrode ANDE2 may be made up of a single layer or multiple layers of one of molybdenum (Mo), aluminum (Al), chromium (Cr), gold (Au), titanium (Ti), nickel (Ni), neodymium (Nd) and copper (Cu) or any alloys thereof.

A second planarization layer 180 may be disposed on the second anode connection electrode ANDE2. The second planarization layer 180 may be formed as an organic layer such as an acryl resin, an epoxy resin, a phenolic resin, a polyamide resin and a polyimide resin.

The emission material layer EML including light-emitting elements LEL and a bank 190 may be disposed on the second planarization layer 180. Each of the light-emitting elements LEL includes a pixel electrode 171, an emissive layer 172, and a common electrode 173.

The pixel electrode 171 may be disposed on the second planarization layer 180. The pixel electrode 171 may be connected to the second anode connection electrode ANDE2 through a third connection contact hole ANCT3 penetrating the second planarization layer 180.

In the top-emission structure in which light exits from the emissive layer 172 toward the common electrode 173, the pixel electrode 171 may include or consist of a metal material having a relatively high reflectivity such as a stack structure of aluminum and titanium (Ti/Al/Ti), a stack structure of aluminum (Al) and Indium Tin Oxide (“ITO”) (ITO/Al/ITO), an APC alloy and a stack structure of an APC alloy and ITO (ITO/APC/ITO). The APC alloy is an alloy of silver (Ag), palladium (Pd) and copper (Cu).

The bank 190 may partition the pixel electrode 171 on the second planarization layer 180 to define the emission areas EA1 and EA2. The bank 190 may be disposed to cover the edges of the pixel electrode 171. The bank 190 may include an organic film such as an acryl resin, an epoxy resin, a phenolic resin, a polyamide resin and a polyimide resin.

In each of the first emission area EA1 and the second emission area EA2, the pixel electrode 171, the emissive layer 172 and the common electrode 173 are stacked on one another sequentially, so that holes from the pixel electrode 171 and electrons from the common electrode 173 are recombined with each other in the emissive layer 172 to emit light.

The emissive layer 172 may be placed on the pixel electrode 171 and the bank 190. The emissive layer 172 may include an organic material to emit light of a particular color. In an embodiment, the emissive layer 172 may include a hole transporting layer, an organic material layer, and an electron transporting layer, for example.

The common electrode 173 may be disposed on the emissive layer 172. The common electrode 173 may cover the emissive layer 172. The common electrode 173 may be a common layer formed commonly across the first emission area EA1 and the second emission area EA2.

In the top-emission organic light-emitting diode, the common electrode 173 may include a transparent conductive material (“TCP”) such as ITO and IZO that may transmit light, or a semi-transmissive conductive material such as magnesium (Mg), silver (Ag) and an alloy of magnesium (Mg) and silver (Ag). When the common electrode 173 is including or consisting of a semi-transmissive metal material, the light extraction efficiency may be increased by microcavities.

A spacer 191 may be disposed on the bank 191. The spacer 191 may support a mask during a process of fabricating the emission layer 172. The spacer 191 may be implemented as an organic layer such as an acryl resin, an epoxy resin, a phenolic resin, a polyamide resin and a polyimide resin.

In an embodiment of the disclosure, the display panel 400 may further include a capping layer CPL disposed on the common electrode 173. The capping layer CPL may include or consist of an inorganic material. In an embodiment, the capping layer CPL may include at least one of: silicon nitride, aluminum nitride, zirconium nitride, titanium nitride, hafnium nitride, tantalum nitride, silicon oxide, aluminum oxide, titanium oxide, tin oxide, cerium oxide and silicon oxynitride, for example.

The encapsulation layer TFEL may be disposed on the common electrode 173. The encapsulation layer TFEL may include at least one inorganic layer to prevent permeation of oxygen or moisture into the emission material layer EML. In addition, the encapsulation layer TFEL may include at least one organic film to protect the emission material layer EML from particles such as dust. In an embodiment, the encapsulation layer TFEL may include a first inorganic encapsulation film TFE1, an organic encapsulation film TFE2 and a second inorganic encapsulation film TFE3, for example.

The first inorganic encapsulation film TFE1 may be disposed on the common electrode 173, the organic encapsulation film TFE2 may be disposed on the first inorganic encapsulation film TFE1, and the second inorganic encapsulation film TFE3 may be disposed on the organic encapsulation film TFE2. The first inorganic encapsulation film TFE1 and the second inorganic encapsulation film TFE3 may be made up of multiple layers in which one or more inorganic layers of a silicon nitride layer, a silicon oxynitride layer, a silicon oxide layer, a titanium oxide layer and an aluminum oxide layer are alternately stacked on one another. The organic encapsulation film TFE2 may be an organic film such as an acryl resin, an epoxy resin, a phenolic resin, a polyamide resin, a polyimide resin, etc.

The touch detecting layer TDL may be disposed on the encapsulation layer TFEL. The touch detecting layer TDL includes a first touch insulating layer TINS1, bridge electrodes BE, a second touch insulating layer TINS2, the driving electrodes TE, the sensing electrodes RE, and a third touch insulating layer TINS3.

The first touch insulating layer TINS1 may be disposed on the encapsulation layer TFEL. The first touch insulating layer TINS1 may be implemented as an inorganic film, e.g., a silicon nitride layer, a silicon oxynitride layer, a silicon oxide layer, a titanium oxide layer, or an aluminum oxide layer.

The bridge electrodes BE may be arranged on the first touch insulating layer TINS1. The bridge electrodes BE may be made up of a single layer or multiple layers of one of molybdenum (Mo), aluminum (Al), chromium (Cr), gold (Au), titanium (Ti), nickel (Ni), neodymium (Nd) and copper (Cu) or any alloys thereof.

The second touch insulating layer TINS2 may be disposed over the bridge electrodes BE. The second touch insulating layer TINS2 may be implemented as an inorganic layer, e.g., a silicon nitride layer, a silicon oxynitride layer, a silicon oxide layer, a titanium oxide layer, or an aluminum oxide layer. In an alternative embodiment, the second touch insulating layer TINS2 may include or consist of an organic layer such as an acryl resin, an epoxy resin, a phenolic resin, a polyamide resin and a polyimide resin.

The driving electrodes TE and the sensing electrodes RE may be arranged on the second touch insulating layer TINS2. The driving electrodes TE and the sensing electrodes RE may be made up of a single layer or multiple layers of one of molybdenum (Mo), aluminum (Al), chromium (Cr), gold (Au), titanium (Ti), nickel (Ni), neodymium (Nd) and copper (Cu) or any alloys thereof.

The driving electrodes TE and the sensing electrodes RE may overlap with the bridge electrodes BE in the third direction DR3. The driving electrodes TE may be connected to the bridge electrodes BE through touch contact holes TCNT1 penetrating through the first touch insulating layer TINS1.

The third touch insulating layer TINS3 may be formed on the driving electrodes TE and the sensing electrodes RE. The third touch insulating layer TINS3 may provide a flat surface over the driving electrodes TE, the sensing electrodes RE and the bridge electrodes BE which have different heights. The third touch insulating layer TINS3 may include or consist of an organic layer such as an acryl resin, an epoxy resin, a phenolic resin, a polyamide resin and a polyimide resin.

FIG. 8 is a plan view of embodiments of a panel support member of the disclosure.

Referring to FIG. 8, the panel support member 700 may include a folding portion 710, a first non-folding portion 720 and a second non-folding portion 730. The folding portion 710 may be disposed in the folding area FDA, the first non-folding portion 720 may be disposed in the first non-folding area NFA1, and the second non-folding portion 730 may be disposed in the second non-folding area NFA2. In the folding area FDA, the grid pattern of the folding portion 710 is disposed. In the first and second non-folding areas NFA1 and NFA2, the grid pattern is not disposed.

The folding portion 710 may be folded when the display device 10 is folded. The folding portion 710 may be disposed between the first non-folding portion 720 and the second non-folding portion 730 in the first direction DR1.

The first non-folding portion 720 and the second non-folding portion 730 may not be folded when the display device 10 is folded. The first non-folding portion 720 may be disposed on one side of the folding portion 710 in the first direction DR1, and the second non-folding portion 730 may be disposed on the opposite side of the folding portion 710 in the first direction DR1.

The folding portion 710 may include a lattice pattern. In an embodiment, the folding portion 710 may include a plurality of bars BAR, and a plurality of slits SLT may be arranged between the plurality of bars BAR, for example.

The plurality of bars BAR may include a plurality of horizontal bars each extended in the first direction DR1, and a plurality of vertical bars each extended in the second direction DR2. The bars BAR of the folding portion 710 may be connected with one another without disconnection, and may connect between the first non-folding portion 720 and the second non-folding portion 730 without disconnection.

Each of the plurality of slits SLT may be a hole penetrating the panel support member 700 in the third direction DR3. The plurality of slits SLT may each extended in the second direction DR2. In an embodiment, the length of each of the plurality of slits SLT in the second direction DR2 may be larger than the length in the first direction DR1, for example. Since the plurality of slits SLT is defined in the folding portion 710, it may have flexibility. That is to say, the foldable portion 710 may be stretched in the first direction DR1 when the display device 10 is folded.

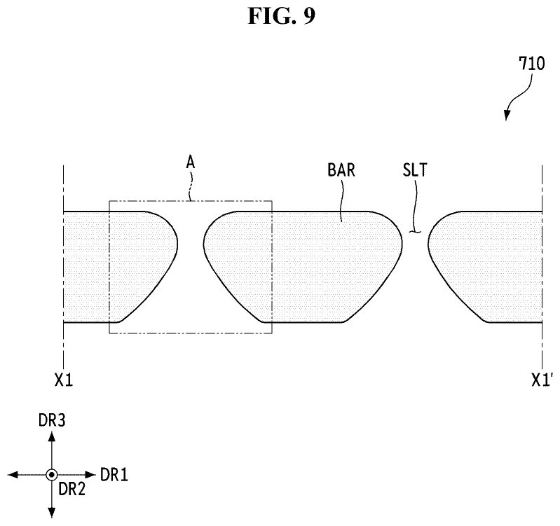

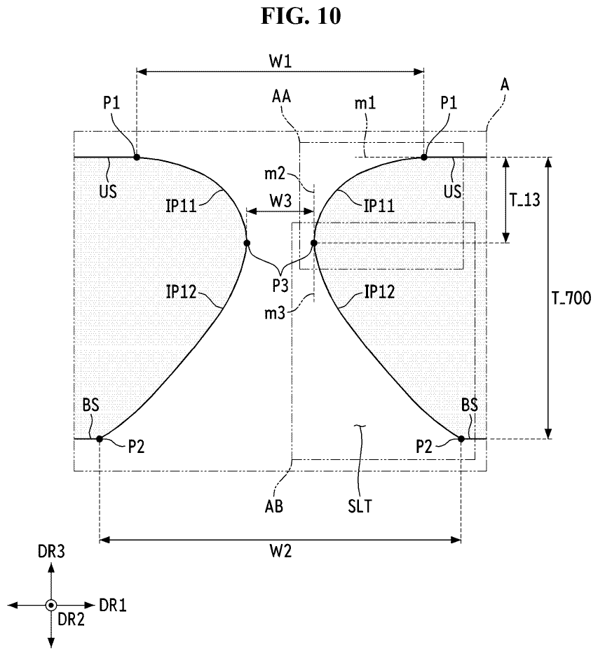

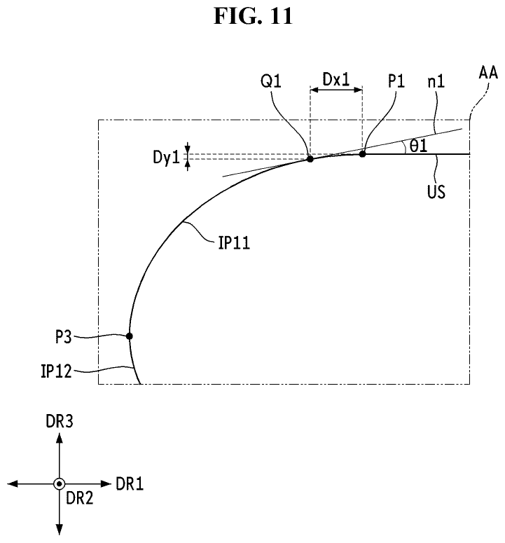

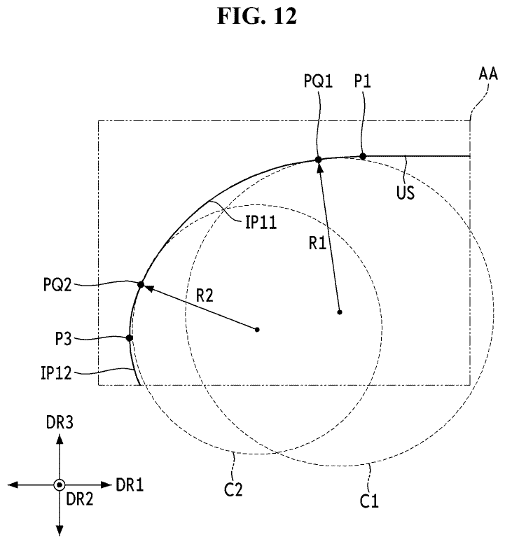

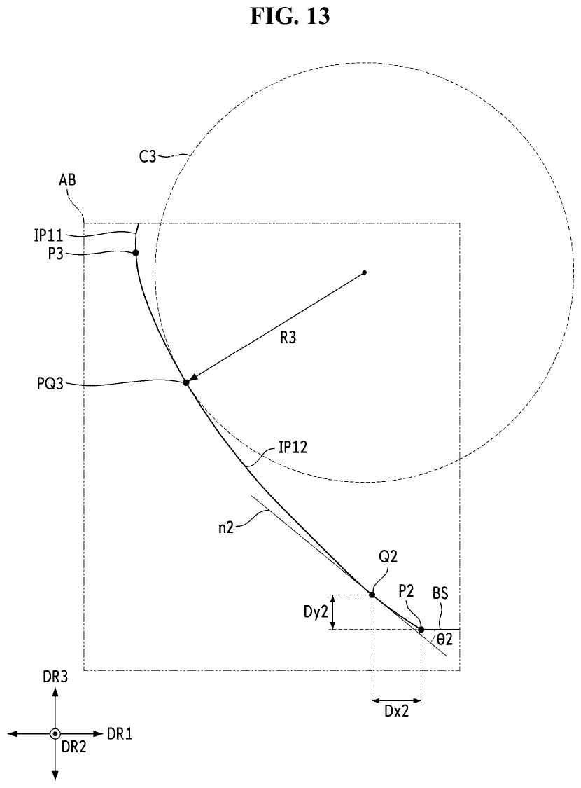

FIG. 9 is a cross-sectional view taken along line X1-X1′ in FIG. 8. FIG. 10 is an enlarged view of area A of FIG. 9. FIG. 11 and FIG. 12 are enlarged views of area AA of FIG. 10. FIG. 13 is an enlarged view of area AB of FIG. 10.

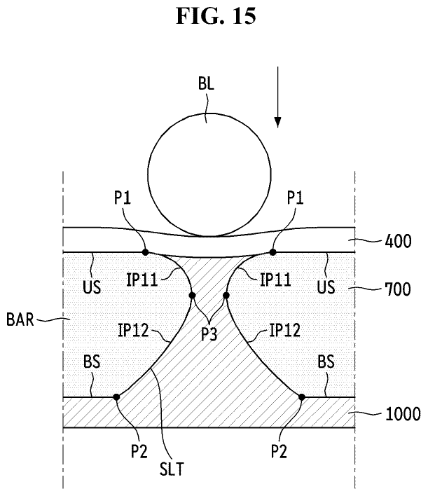

In FIG. 9, FIG. 10, FIG. 11, FIG. 12 and FIG. 13, the filling member 1000 (refer to FIG. 15) inside the slit SLT is not depicted for convenience of illustration.

Referring to FIG. 9, FIG. 10, FIG. 11, FIG. 12 and FIG. 13 in conjunction with FIG. 8, the panel support member 700 may include an upper surface US, a lower surface BS, a first inner surface IP11, and a second inner surface IP12.

The upper surface US and the lower surface BS may face each other in the third direction DR3. The first inner surface IP11 and the second inner surface IP12 may be side surfaces of a slit SLT. The first inner surface IP11 may be connected to the upper surface US, and the second inner surface IP12 may be connected to the lower surface BS. Accordingly, the upper surface US, the first inner surface IP11, the second inner surface IP12 and the lower surface BS may be connected with one another in this order.

The point where the upper surface US and the first inner surface IP11 meet each other may be a first point P1, the point where the lower surface BS and the second inner surface IP12 meet each other may be a second point P2, and the point where the first inner surface IP11 and the second inner surface IP12 meet each other may be a third point P3.

The upper surface US and the lower surface BS may be flat, while the first inner surface IP11 and the second inner surface IP12 may be curved. In an embodiment, in a cross-section cut along the plane defined by the first direction DR1 and the third direction DR3, the upper surface US and the lower surface BS may be straight lines extended in the first direction DR1, while the first inner surface IP11 and the second inner surface IP12 may be curved lines, for example.

Among the surfaces of the panel support member 700, the first surface with the curvature of zero may be defined as the upper surface US, the point at which the curvature becomes greater than zero from the upper surface US may be defined as the first point P1, and the surface with a curvature greater than zero from the first point P1 may be defined as the first inner surface IP11. Among the surfaces of the panel support member 700, the second surface with the curvature of zero which is opposed to the upper surface US may be defined as the lower surface BS, the point at which the curvature becomes greater than zero from the lower surface BS may be defined as the second point P2, and the surface with a curvature greater than zero from the second point P2 may be defined as the second inner surface IP12.

In an embodiment, a first tangent m1 that touches the first inner surface IP11 at the first point P1 may be extended parallel to the upper surface US. Specifically, the slope of the first tangent m1 of the first inner surface IP11 may be equal to the slope of the upper surface US at the first point P1. Accordingly, the first inner surface IP11 and the upper surface US maintain tangent continuity and are connected in a differentiable manner, so that they may be smoothly connected without a vertex.

In an embodiment, the second tangent m2 that touches the first inner surface IP11 at the third point P3 may be extended parallel to the third tangent m3 that touches the second inner surface IP12 at the third point P3. In other words, the slope of the second tangent m2 may be equal to the slope of the third tangent m3 at the third point P3. Accordingly, the first inner surface IP11 and the second inner surface IP12 maintain tangent continuity and are connected in a differentiable manner, so that they may be smoothly connected without a vertex.

In a cross-section cut along the plane defined by the first direction DR1 and the third direction DR3, a plurality of slits SLT may have a shape with different widths in the first direction DR1 depending on their positions in the third direction DR3.

In an embodiment, a first width W1, which is the width of the upper opening of the slit SLT, may be smaller than a second width W2, which is the width of the lower opening of the slit SLT, for example. A third width W3, which is the width of the narrowest portion of the slit SLT, may be smaller than the first width W1, which is the width of the upper opening of the slit SLT. The slits SLT may have the third width W3 as the minimum width.

The first width W1 may be the width of the slit SLT at a position parallel to the upper surface US in a horizontal direction (e.g., the first direction DR1), the second width W2 may be the width of the slit SLT at a position parallel to the lower surface BS in a horizontal direction (e.g., the first direction DR1), and the third width W3 may be the width of the slit SLT at a position parallel to the third point P3 in a horizontal direction (e.g., the first direction DR1). In an embodiment, the first width W1 may be the distance between the first points P1 on the opposite sides of the slit SLT, respectively, the second width W2 may be the distance between the second points P2 on the opposite sides of the slit SLT, respectively, and the third width W3 may be the distance between the third points P3 on the opposite sides of the slit SLT, respectively, for example.

In an embodiment of the disclosure, the first width W1 may range from approximately 20 μm to 80 μm, the second width W2 may range from approximately 40 μm to 150 μm, and the third width W3 may range from approximately 10 μm to 40 μm. In an embodiment, a distance T_13 between the third point P3 and the upper surface US in the third direction DR3 may be greater than about 0.2 times and less than about 0.4 times the thickness T_700 of the panel support member 700. In an embodiment, when the thickness T_700 of the panel support member 700 is approximately 80 μm to 150 μm, the distance T_13 between the third point P3 and the upper surface US in the third direction DR3 may be greater than about 15 μm and less than about 60 μm, for example.

In the display device 10 in the embodiment, the width of the upper opening of the slit SLT of the panel support member 700 is narrower than the width of the lower opening, so that the area where the panel support member 700 and the display panel 400 contact increases. As a result, the panel support member 700 may better support the display panel 400. In this manner, the durability of the display device 10 may be improved.

In addition, since the width of the lower opening of the slit SLT of the panel support member 700 is wider than the width of the upper opening, the stress applied to the panel support member 700 is reduced when the display device 10 is in-folding, so that the flexibility of the display device 10 may be improved.

As shown in FIG. 11, a first reference point Q1 may be defined where a straight line extended in a horizontal direction (e.g., the first direction DR1) at a point distant from the first point P1 by a first vertical distance Dy1 in a vertical direction (e.g., the third direction DR3) and the first inner surface IP11 meet. In an embodiment of the disclosure, the first vertical distance Dy1 may be 0.5 μm. The first vertical distance Dy1 may be the maximum allowable distance that does not cause damage to the display panel 400 when the display panel 400 disposed on the panel support member 700 is pressed into the slit SLT by an external pressure and is deformed.

The first reference point Q1 may be spaced apart from the first point P1 in the horizontal direction (e.g., the first direction DR1) by a first horizontal distance Dx1. The first horizontal distance Dx1 may be 2 times to 4 times the first vertical distance Dy1. In an embodiment, when the first vertical distance Dy1 is approximately 0.5 μm, the first horizontal distance Dx1 may range from approximately 1 μm to 2 μm, for example.

In an embodiment, a first angle θ1 defined by a first tangent n1 touching the first inner surface IP11 at the first point Q1 and the upper surface US may range from 15 degrees to 30 degrees.

In the display device 10 in the illustrative embodiment, the first angle θ1 measured based on the first reference point Q1 spaced apart by the first vertical distance Dy1 that is the maximum allowable distance not causing damage to the display panel 400 is 30 degrees or less, so that deformation of the display panel 400 due to pressing may be suppressed. In an embodiment, since the first angle θ1 is 30 degrees or less while the display panel 400 is deformed by being pressed to the first vertical distance Dy1, which is the maximum allowable distance, the first inner surface IP11 may form a gentle curve between the first point P1 and the first reference point Q1, for example. Accordingly, the deformation of the display panel 400 between the first point IP11 and the first reference point Q1 may be suppressed.

As shown in FIG. 13, a second reference point Q2 may be defined where a straight line extended in a horizontal direction (e.g., the first direction DR1) at a point that is distant from the second point P2 by a second vertical distance Dy2 in a vertical direction (e.g., the third direction DR3) and the second inner surface IP12 meet. The second reference point Q2 may be spaced apart from the second point P2 in the horizontal direction (e.g., the first direction DR1) by a second horizontal distance Dx2. The second horizontal distance Dx2 may be 1 times to 2 times the second vertical distance Dy2.

In an embodiment, a second angle θ2 defined by a second tangent n2 touching the second inner surface IP12 at the second point Q2 and the lower surface BS may be greater than the first angle θ1. In an embodiment of the disclosure, the second vertical distance Dy2 may be 0.5 μm, which is equal to the first vertical distance Dy1.

As shown in FIG. 12, a first contact point PQ1 and a second contact point PQ2 disposed on the first inner surface IP11 may be defined, respectively. The first contact point PQ1 may be disposed next (adjacent) to the first point P1, and the second contact point PQ2 may be disposed next (adjacent) to the third point P3. The distance (the distance along the first inner surface IP11) between the first contact point PQ1 and the first point P1 may be equal to the distance between the second contact point PQ2 and the third point P3 on the first inner surface IP11. In other words, the distance between the first point P1 and the first contact point PQ1 on the first inner surface IP11 may be equal to the distance between the second point P2 and the second contact point PQ2 on the first inner surface IP11.

In an embodiment, a first radius R1 of a first inscribed circle C1 touching the first inner surface IP11 at the first contact point PQ1 may be greater than a second radius R2 of a second inscribed circle C2 touching the first inner surface IP11 at the second contact point PQ2. That is to say, the radius of curvature of the first inner surface IP11 at the first contact point PQ1 may be greater than the radius of curvature of the first inner surface IP11 at the second contact point PQ2.

In an embodiment of the disclosure, the radius of curvature of the first inner surface IP11 measured at any point of the first inner surface IP11 may be in a range of approximately 0.3 to 0.5 times the thickness T_700 of the panel support member 700. In an embodiment, the radius of curvature of the first inner surface IP11 measured at any point of the first inner surface IP11 may be in the range of 20 μm to 80 μm, for example.

As shown in FIG. 13, an arbitrary third contact point PQ3 disposed on the second inner surface IP12 may be defined. The third contact point PQ3 may be any point disposed between the second point P2 and the third point P3 on the second inner surface IP12.

In an embodiment, a third radius R3 of a third inscribed circle C3 touching the second inner surface IP12 at the third contact point PQ3 may be greater than the first radius R1 and the second radius R2. In other words, the radius of curvature measured at any point on the second inner surface IP12 may be greater than the radius of curvature measured at any point on the first inner surface IP11.

In an embodiment, the panel support member 700 may have a shape optimization index Ω of 0.35 or greater defined by Equation 1 below:

$$Ω = 100 \cdot \frac{D}{B ( B - A )} \qquad [ Equation l ]$$

where the third width W3 is defined as A, the first width W1 is defined as B, and the distance T_13 in the third direction DR3 between the third point P3 and the upper surface US is defined as D.

The shape optimization index Q indicates the optimal shape of the slit SLT for stably supporting the display panel 400 and increasing durability.

In the display device 10 in the illustrative embodiment, as the first width W1 (the value of B in Equation 1) becomes narrower (i.e., as the shape optimization index Q becomes larger), the durability of the display panel 400 placed on the panel support member 700 may be improved. In addition, it is possible to prevent crease caused by the slit SLT from being seen. Since the shape optimization index Q may become infinitely larger as the first width W1 (the value of B in Equation 1) becomes infinitely narrower (or closer to 0), the upper limit of the shape optimization index Q may not be limited.

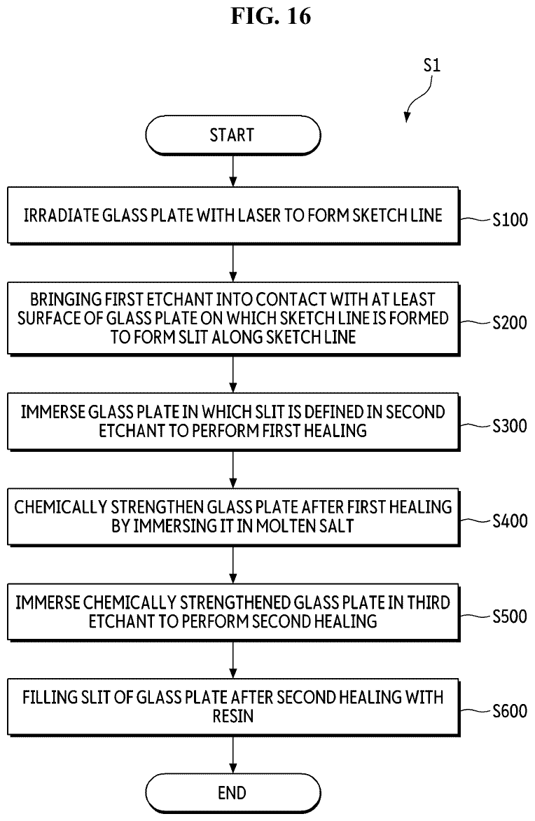

In addition, the first inner surface IP11 and the upper surface US are smoothly connected, and the first angle θ1 decreases, which is the slope of the first tangent n1 in the area from the first point P1 to the first reference point Q1 of the first inner surface IP11, it is possible to suppress damage caused by pressing the display panel 400. Herein, the first angle θ1 is a value related to the slope of the first inner surface IP11, and the value of D/(B−A) in Equation 1 is correlated with the first angle θ1. As the value of D/(B−A) increases, the shape optimization index Q may increase. The value of D, which is the distance T_13 in the third direction DR3 between the third point P3 and the upper surface US, may be limited within a predetermined range (more than 0.2 times and less than 0.4 times) of the thickness T_700 of the panel support member 700, as described above, according to etching process conditions of the method S1 for fabricating a display device described later (refer to FIG. 16). Accordingly, as the value of (B−A) decreases, the shape optimization index Q may increase.

Incidentally, as described above, since the radius of curvature measured at any point on the second inner surface IP12 is greater than the radius of curvature measured at any point on the first inner surface IP11, and the second angle θ2 is greater than the first angle θ1, the second width W2 may be defined larger than the first width W1. Accordingly, the stress applied to the panel support member 700 while the display device 10 is folded inward may be reduced, so that the flexibility of the display device 10 may be improved.

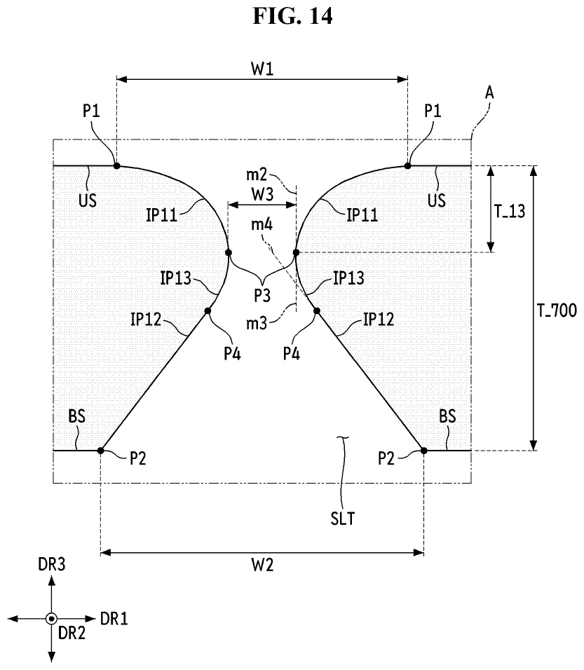

FIG. 14 is an enlarged view showing another embodiment of area A of a panel support member. FIG. 14 shows another embodiment of the panel support member in the embodiment described with reference to FIG. 10 or the like. FIG. 14 does not show the filling member 1000 in the slits SLT for the sake of clarity. In the following descriptions, the same or similar elements will be denoted by the same or similar reference numerals, and redundant descriptions will be omitted or briefly described.

Referring to FIG. 14 in conjunction with FIGS. 8, 9 and 10, the panel support member 700 may include an upper surface US, a lower surface BS, a first inner surface IP11, a second inner surface IP12 and a third inner surface IP13.

The upper surface US and the lower surface BS may face each other in the third direction DR3. The first inner surface IP11, the second inner surface IP12 and the third inner surface IP13 may be side surfaces of a slit SLT. The first inner surface IP11 may be connected to the upper surface US, the second inner surface IP12 may be connected to the lower side BS, and the third inner surface IP13 may connect between the first inner surface IP11 and the second inner surface IP12. Accordingly, the upper surface US, the first inner surface IP11, the third inner surface IP13, the second inner surface IP12 and the lower surface BS may be connected with one another in this order.

The point where the upper surface US and the first inner surface IP11 meet each other may be a first point P1, the point where the lower surface BS and the second inner surface IP12 meet each other may be a second point P2, the point where the first inner side surface IP11 and the third inner surface IP13 meet each other may be a third point P3, and the point where the second inner surface IP12 and the third inner surface IP13 meet each other may be a fourth point P4.

The upper surface US, the lower surface BS and the second inner surface IP12 may be flat, and the first inner surface IP11 and the third inner surface IP13 may be curved. In an embodiment, in a cross-section cut along the plane defined by the first direction DR1 and the third direction DR3, the upper surface US and the lower surface BS may be straight lines extended in the first direction DR1, the second inner surface IP12 may be a straight line extended in a diagonal direction defined by the first direction DR1 and the third direction DR3, and the first inner surface IP11 and the second inner surface IP12 may be curved lines, for example.

Among the surfaces of the panel support member 700, the first surface with the curvature of zero may be defined as the upper surface US, the point at which the curvature becomes greater than zero from the upper surface US may be defined as the first point P1, and the surface with a curvature greater than zero from the first point P1 may be defined as the first inner surface IP11. Among the surfaces of the panel support member 700, the second surface with the curvature of zero which is opposed to the upper surface US may be defined as the lower surface BS, the point at which the curvature becomes different from the lower surface BS may be defined as the second point P2, and the surface with a different curvature from the second point P2 may be defined as the second inner surface IP12. The point at which the curvature becomes greater than zero from the second inner surface IP12 may be defined as the fourth point P4, and the surface with a curvature greater than zero from the fourth point P4 may be defined as the third inner surface IP11. The third point P3 where the first inner surface IP11 and the third inner surface IP13 meet each other may be defined as the point where the narrowest portion of the slit SLT is disposed.

The second tangent m2 that touches the first inner surface IP11 at the third point P3 may be extended parallel to the third tangent m3 that touches the third inner surface IP13 at the third point P3. In other words, the slope of the second tangent m2 may be equal to the slope of the third tangent m3 at the third point P3. Accordingly, the first inner surface IP11 and the third inner surface IP13 maintain tangent continuity and are connected in a differentiable manner, so that they may be smoothly connected without a vertex.

At the fourth point P4, a fourth tangent m4 that touches the third inner surface IP13 may be extended parallel to the second inner surface IP12. Specifically, the slope of the first tangent m1 of the third inner surface IP13 may be equal to the slope of the second inner surface IP12 at the fourth point P4. Accordingly, the second inner surface IP12 and the third inner surface IP13 maintain tangent continuity and are connected in a differentiable manner, so that they may be smoothly connected without a vertex.

FIG. 15 is a cross-sectional view showing embodiments of a ball drop test conducted on the stack structure of a display panel and a panel support member.

Referring to FIG. 15, in the panel support member 700 in the embodiments, the upper surface US and the first inner surface IP11 are smoothly connected with each other at the first point P1, and the first inner surface IP11 and the second inner surface IP12 (or the third inner surface IP13) (refer to FIG. 14) are smoothly connected with each other at the third point P3, so that the durability of the display device 10 may be improved.

In an embodiment, since the upper surface US and the first inner surface IP11 are smoothly connected with each other at the first point P1, no tip is formed, for example. Accordingly, even when the display panel 400 is subject to pressure, like in the ball drop test using a ball BL, damage to the display panel 400 at the first point P1 may be reduced.

In addition, as in the method S1 for fabricating the display device described later, the filling member 1000 is formed by being filled with a resin and then cured. Since the upper surface US and the first inner surface IP11 are smoothly connected with each other at the second point P2, no tip is formed. Accordingly, the panel support member 700 and the filling member 1000 may be firmly combined. As a result, the durability of the panel support member 700 may be improved.

Incidentally, since the slit SLT is narrowest at the third point P3 and has relatively wider widths at the first point P1 and the second point P2, the filling member 1000 may be firmly bonded to the panel support member 700 after the resin has been cured. Specifically, the portion of the filling member 1000 that contacts the first inner surface IP11 is engaged with the panel support member 700 in a hook shape, so that the panel support member 700 and the filling member 1000 may be firmly coupled together without being easily separated from each other. As a result, the durability of the panel support member 700 may be improved.

Hereinafter, a method for fabricating a display device in an embodiment of the disclosure will be described.

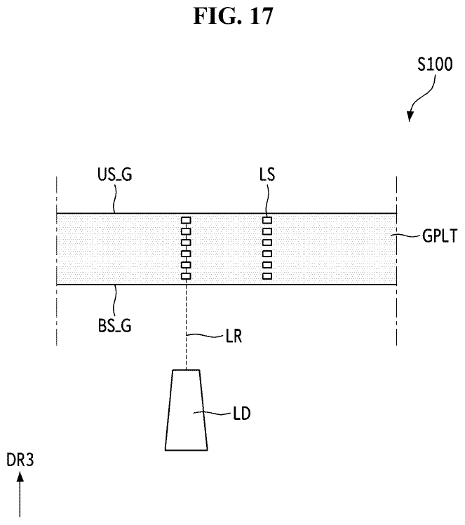

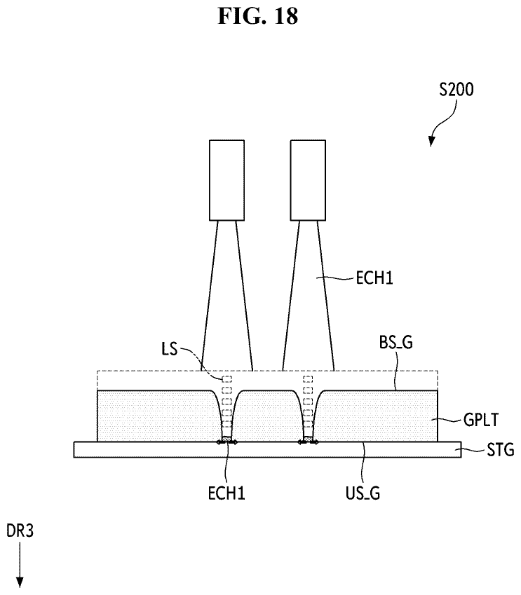

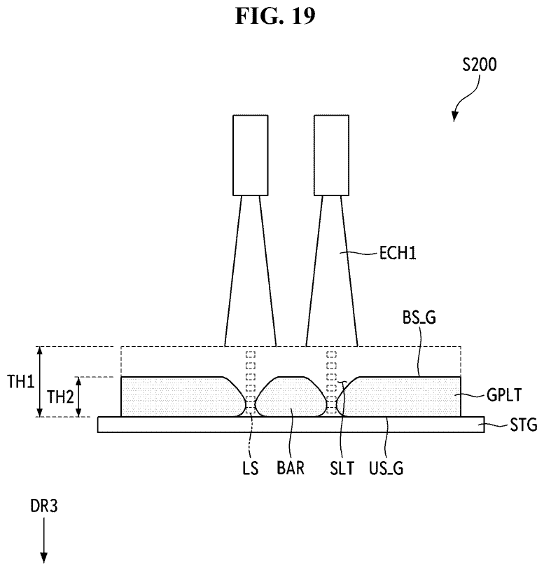

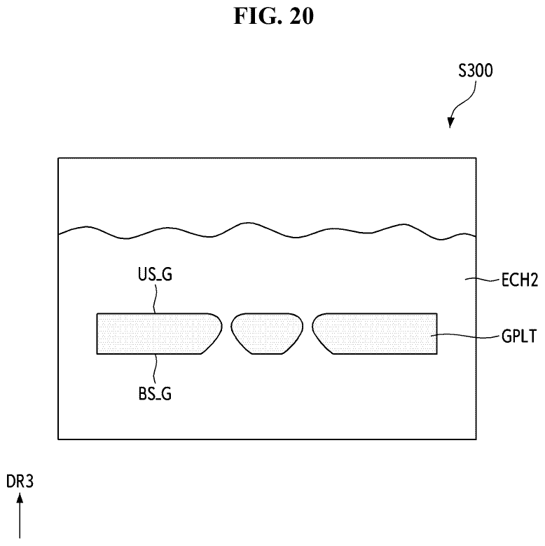

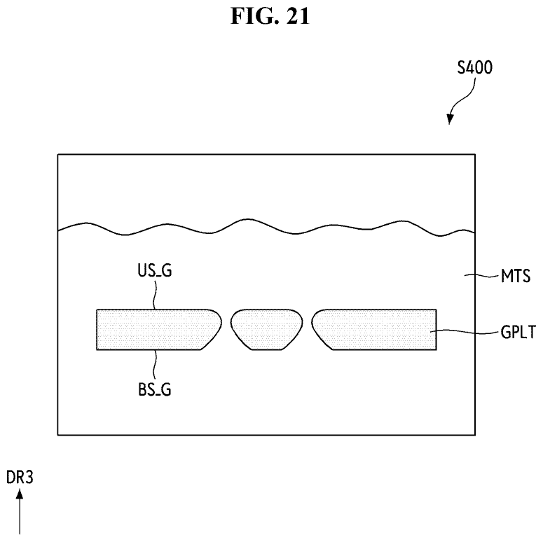

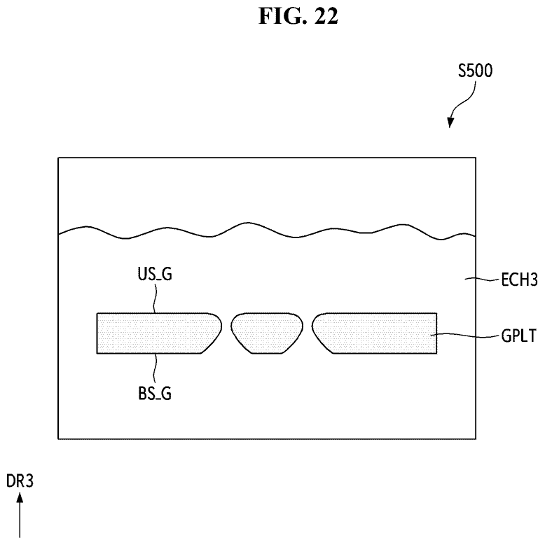

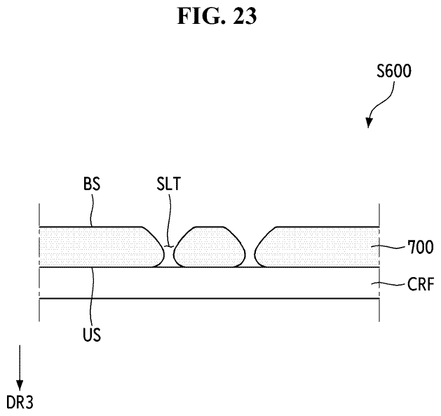

FIG. 16 is a flowchart for illustrating embodiments of a method for fabricating a display device of the disclosure. FIG. 17 is a cross-sectional view showing operation S100 of FIG. 16. FIG. 18 and FIG. 19 are cross-sectional views showing operation S200 of FIG. 16. FIG. 20 is a cross-sectional view showing operation S300 of FIG. 16. FIG. 21 is a cross-sectional view showing operation S400 of FIG. 16. FIG. 22 is a cross-sectional view showing operation S500 of FIG. 16. FIGS. 23 to 26 are cross-sectional views showing operation S600 of FIG. 16.

Referring to FIGS. 16 to 26, the method S1 for fabricating a display device in the illustrative embodiment may include: forming a sketch line by irradiating a glass plate with a laser (operation S100); bringing a first etchant into contact with at least a surface of the glass plate on which the sketch line is formed to defined a slit in an area corresponding to the sketch line (operation S200); immersing the glass plate on which the slit is defined in a second etchant to perform first healing (operation S300); chemically strengthening the glass plate after the first healing by immersing it in molten salt (operation S400); immersing the chemically strengthened glass plate in a third etchant to perform second healing (operation S500); and filling the slit of the glass plate after the second healing with a resin (operation S600).

Initially, as shown in FIG. 17, laser LR may be irradiated onto a glass plate GPLT to form a sketch line LS (S100 of FIG. 16).

A laser processing device LD may irradiate the glass plate GPLT with laser LR. As shown in the drawings, the laser processing device LD may irradiate the laser LR onto a surface BS_G of the glass plate GPLT, but the disclosure is not limited thereto. The laser processing device LD may also irradiate the laser LR onto the opposite surface US_G of the glass plate GPLT. Herein, the surface BS_G of the glass plate GPLT may become the lower surface BS of the display device 10 (refer to FIG. 10) described above with reference to FIG. 10, etc. after the process of fabricating the display device is completed. The opposite surface US_G of the glass plate GPLT may become the upper surface US of the display device 10 (refer to FIG. 10) described above with reference to FIG. 10, etc. after the process of fabricating the display device is completed.

In an embodiment of the disclosure, the laser processing device LD may use a picosecond or femtosecond laser beam in an infrared wavelength as the laser LR. The laser processing device LD may use a Bessel beam or a focused beam through an objective lens as the laser LR.

When the laser processing device LD irradiates the glass plate GPLT with the laser LR, a sketch line LS may be formed on the glass plate GPLT. The sketch line LS may include of a plurality of spots as shown in the drawings, but the disclosure is not limited thereto. The sketch line LS may be formed as a single line. The sketch line LS may be a guide line or an induced line for controlling the shape of a slit SLT prior to forming the shape of the slit SLT by etching using a first etchant ECH1 described later.

In an embodiment, the process of forming the sketch line LS by irradiating the laser LR may be performed by a laser drilling process. The laser drilling process refers to a process of partially removing the glass plate GPLT or drilling it by irradiating the laser LR. Accordingly, the sketch line LS may include a plurality of physically removed (or drilled) through holes.

In another embodiment, the process of forming the sketch line LS by irradiating the laser LR may be performed by a laser modification process. The laser modification process refers to a process that locally changes the physical or chemical properties of the glass plate GPLT by laser (LR) irradiation. Accordingly, the sketch line LS may include a modified region in which the physical or chemical properties are changed.

Subsequently, as shown in FIGS. 18 and 19, the first etchant ECH1 may be brought into contact with at least a surface of the glass plate GPLT on which the sketch line LS is formed, thereby defining a slit SLT along the sketch line LS (S200 of FIG. 16).

In an embodiment, the first etchant ECH1 may be sprayed onto at least one surface of the glass plate GPLT. In an embodiment, the first etchant ECH1 may be sprayed onto the surface BS_G of the glass plate GPLT, for example. The first etchant ECH1 may include ammonium ions (NH₄⁺) and bifluoride ions (HF₂⁻). In an embodiment, in the first etchant ECH1, the sum of the mole percentages (mol %) of ammonium ions (NH4+) and bifluoride ions (HF2−) relative to the total material may be less than approximately 30 mol %, for example. In an embodiment of the disclosure, the etching rate of the glass plate GPLT by the first etchant ECH1 may be approximately 5 micrometers per minute (m/min) to 15 m/min.

In another embodiment, although not shown in the drawings, the glass plate GPLT may be immersed in the first etchant ECH1 and may contact the first etchant ECH1. In an embodiment, the glass plate GPLT may be placed on a stage STG (or a carrier substrate, a roller, etc.) and immersed in a tank in which the first etchant ECH1 is stored, for example. At this time, since the opposite surface US_G of the glass plate GPLT contacts one surface of the stage STG, the glass plate GPLT may not directly contact the first etchant ECH1 at the moment when it is immersed in the first etchant ECH1. The surface BS_G of the glass plate GPLT may directly contact the first etchant ECH1 at the moment when the glass plate GPLT is immersed in the first etchant ECH1. Accordingly, the glass plate GPLT may be processed into the same shape as that when the first etchant ECH1 is sprayed on at least one surface of the glass plate GPLT.

Hereinafter, an example will be described where the first etchant ECH1 is sprayed on the glass plate GPLT.

The thickness of the glass plate GPLT may be slimmed by etching with the first etchant ECH1. A first thickness TH1, which is the initial thickness of the glass plate GPLT, may be reduced to a second thickness TH2. In an embodiment of the disclosure, the first thickness TH1 may be approximately 200 micrometers (μm) to 300 μm, and the second thickness TH2 may be approximately 80 μm to 150 μm. It should be understood, however, that the embodiments of the disclosure are not limited thereto.

As shown in FIG. 19, while the first etchant ECH1 is sprayed directly onto the surface BS_G of the glass plate GPLT, the opposite surface US_G of the glass plate GPLT is in direct contact with the stage STG, so that the time (or degree) of contact with the first etchant ECH1 may be smaller on the opposite surface US_G of the glass plate GPLT than on the surface BS_G. As a result, a slit SLT which has a wider opening on the surface BS_G than on the opposite surface US_G of the glass plate GPLT may be defined.

Incidentally, as shown in FIG. 18, the first etchant ECH1 may quickly move from the surface BS_G to the opposite surface US_G along the sketch line LS. Once the first etchant ECH1 reaches the boundary between the opposite surface US_G and the surface of the stage STG, the first etchant ECH1 may remain in the internal space of the etched glass plate GPLT. The remaining first etchant ECH1 may etch the vicinity of the opposite surface US_G of the glass plate GPLT while spreading along the boundary between the opposite surface US_G and the surface of the stage STG. In this manner, etching may proceed faster in the vicinity of the opposite surface US_G of the glass plate GPLT than at the narrowest portion of the slit SLT. As a result, the width may be larger in the vicinity of the opposite surface US_G of the glass plate GPLT than at the narrowest portion of the slit SLT.

Subsequently, as shown in FIG. 20, the glass plate GPLT in which the slit SLT is defined may be immersed in a second etchant ECH2 (first healing) (S300 in FIG. 16).

The glass plate GPLT in which the slit SLT is defined may be immersed in a second etchant ECH2. The glass plate GPLT immersed in the second etchant ECH2 may be etched slowly mainly on the surface in contact with the second etchant ECH2. Accordingly, surface defects of the glass plate GPLT may be repaired or alleviated, and surface roughness may be reduced. In other words, the durability of the glass plate GPLT may be improved.

The second etchant ECH2 may include or consist of ammonium ions (NH₄⁺) and bifluoride ions (HF₂⁻), like the first etchant ECH1. The ratio of ammonium ions (NH₄⁺) to the total ions in the second etchant ECH2 may be different from the ratio of ammonium ions (NH₄⁺) to the total ions in the first etchant ECH1. The ratio of bifluoride ions (HF₂⁻) to the total ions in the second etchant ECH2 may be different from the ratio of bifluoride ions (HF₂⁻) to the total ions in the first etchant ECH1. In an embodiment, the ratio of ammonium ions (NH4+) to the total ions in the first etchant ECH1 may be smaller than the ratio of ammonium ions (NH4+) to the total ions in the second etchant ECH2, for example. The ratio of bifluoride ions (HF₂⁻) to the total ions in the first etchant ECH1 may be greater than the ratio of bifluoride ions (HF₂⁻) to the total ions in the second etchant ECH2.

Accordingly, the etching rate of the glass plate GPLT by the second etchant ECH2 may be slower than the etching rate of the glass plate GPLT by the first etchant ECH1. In an embodiment, the etching rate of the glass plate GPLT by the second etchant ECH2 may be approximately 0.5 μm/min to 3 μm/min, for example.

Subsequently, as shown in FIG. 21, the glass plate GPLT after the first healing may be chemically strengthened by immersing it in molten salt MTS (S400 in FIG. 16).

The glass plate GPLT after the first healing may be immersed in molten salt MTS. The durability of the glass plate GPLT immersed in the molten salt MTS may be improved by ion exchange. In an embodiment, the molten salt MTS may include potassium nitrate (KNO₃). In an embodiment, potassium ions (K+) of the potassium nitrate (KNO3) may be exchanged with sodium ions (Na+) of the glass plate GPLT, for example. In an embodiment of the disclosure, the temperature at which the strengthening process is performed may be approximately 320° C. to 420° C.

Accordingly, the compressive stress of the glass plate GPLT may be improved. In an embodiment, the compressive stress of the glass plate GPLT after the strengthening process may be approximately 500 megapascals (MPa) to 900 Mpa, for example. The depth (or compressive depth: depth of layer) may be approximately 5 μm to 10 μm.

Subsequently, as shown in FIG. 22, the chemically strengthened glass plate GPLT may be immersed in a third etchant ECH3 (second healing) (S500 in FIG. 16).

The strengthened glass plate GPLT may be immersed in the third etchant ECH3. The glass plate GPLT immersed in the third etchant ECH3 may be etched slowly mainly on the surface in contact with the third etchant ECH3. Accordingly, surface defects of the glass plate GPLT may be repaired or alleviated, and surface roughness may be reduced. In other words, the durability of the glass plate GPLT may be improved.

The third etchant ECH3 may include or consist of ammonium ions (NH₄⁺) and bifluoride ions (HF₂⁻), like the first etchant ECH1 and the second etchant ECH2. In an embodiment, the third etchant ECH3 may include or consist of substantially the same material as that of the second etchant ECH2. In an embodiment, the ratio of ammonium ions (NH4+) to the total ions in the third etchant ECH3 may be substantially equal to the ratio of ammonium ions (NH4+) to the total ions in the second etchant ECH2, for example. The ratio of bifluoride ions (HF₂⁻) to the total ions in the third etchant ECH3 may be substantially equal to the ratio of bifluoride ions (HF₂⁻) to the total ions in the second etchant ECH2.

Accordingly, the etching rate of the glass plate GPLT by the third etchant ECH3 may be slower than the etching rate of the glass plate GPLT by the first etchant ECH1. In an embodiment, the etching rate of the glass plate GPLT by the third etchant ECH3 may be approximately 0.5 μm/min to 3 μm/min, for example.

In an embodiment, the second healing process using the third etchant ECH3 may be performed for a shorter time than the first healing process using the second etchant ECH2. Accordingly, the amount of etching in the second healing process using the third etchant ECH3 may be less than the amount of etching in the first healing process using the second etchant ECH2. In an embodiment, the amount of etching in the second healing process using the third etchant ECH3 may be approximately 0.5 μm to 2 μm, and the amount of etching in the first healing process using the second etchant ECH2 may be approximately 1 μm to 10 μm, for example.

Subsequently, as shown in FIGS. 23 to 26, the slit SLT of the glass plate GPLT after the second healing may be filled with resin RSN (S600 in FIG. 16).

After the second healing process of the glass plate GPLT has been completed, a panel support member 700 may be formed.

As shown in FIG. 23, a carrier film CRF may be laminated on the upper surface US of the panel support member 700. The opening of the slit SLT next (adjacent) to the upper surface US may be covered with the carrier film CRF and thus sealed. Since the carrier film CRF is not disposed on the lower surface BS, the opening of the slit SLT next (adjacent) to the lower surface BS may be open without being sealed.

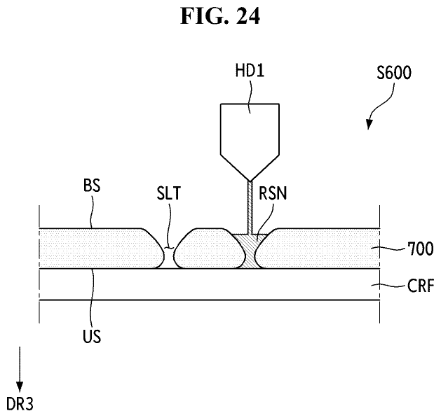

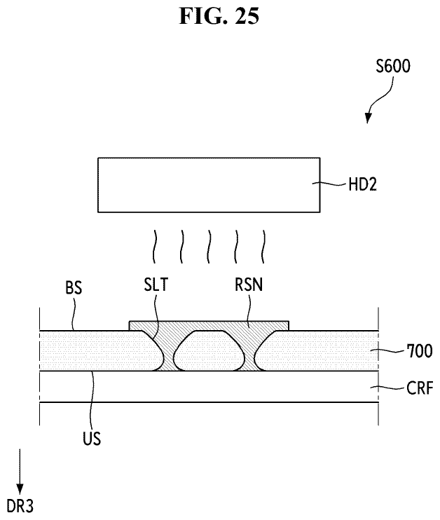

Then, as shown in FIG. 24, a first head HD1 may apply a liquid resin RSN onto the slit SLT. The first head HD1 may apply the liquid resin (hereinafter also referred to a resin) RSN by jetting or printing (slit printing). As shown in FIG. 25, the resin RSN may be applied (overcoated) such that it is higher than the lower surface BS of the panel support member 700, i.e., such that the lower surface BS overflows with the resin. In an embodiment of the disclosure, the thickness of the overcoated portion of the resin RSN after curing may be, but is not limited to, approximately 5 μm to 10 μm.

Then, as shown in FIG. 25, a second head HD2 may cure the liquid resin RSN. The second head HD2 may cure the resin RSN by thermal curing or UV curing. In another embodiment, the resin RSN may be cured under natural curing without the second head HD2.

In an embodiment, the shear modulus of the resin RSN after curing may be less than approximately 100 MPa. The shear modulus may be measured according to the ISO 1922 standard.

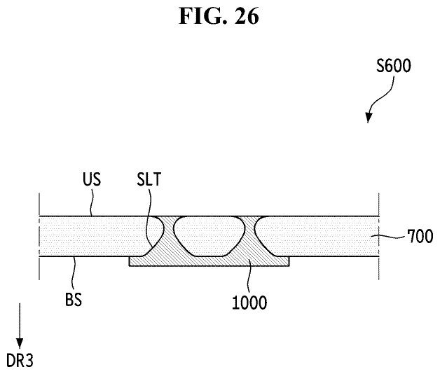

Accordingly, as shown in FIG. 26, the panel support member 700 may be formed in which a filling member 1000 is combined inside the slit SLT and the lower surface BS.

According to the method S1 for fabricating a display device in the illustrative embodiment, by forming the panel support member 700 in the above-described shape (refer to FIG. 10, etc.) by the laser process and the etching process of the first etchant ECH1, the durability and flexibility of the display device 10 may be improved. Additionally, the durability of the panel support member 700 may be improved through the first healing process, the chemical strengthening process, the second healing process, and the resin filling process.

The display device 10 according to the above-described embodiments may be applied to a variety of electronic devices 1. The electronic device 1 in the embodiment may include the above-described display device 10, and may further include a module or device having additional functions in addition to the display device 10.

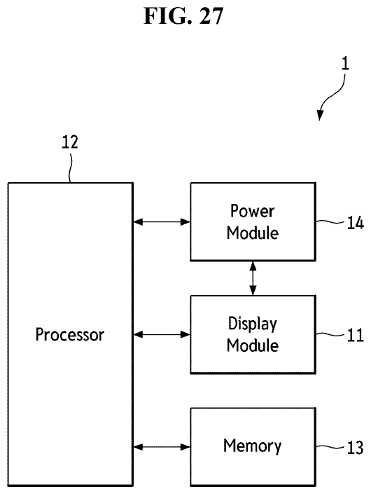

FIG. 27 is a block diagram of an embodiment of an electronic device of the disclosure.

Referring to FIG. 27, an electronic device 1 in an embodiment of the disclosure may include a display module 11, a processor 12, a memory 13, and a power module 14.

The processor 12 may include at least one of: a central processing unit (“CPU”), an application processor (“AP”), a graphic processing unit (“GPU”), a communication processor (“CP”), an image signal processor (“ISP”), and a controller.

The memory 13 may store data information desired for the operation of the processor 12 or the display module 11. When the processor 12 executes an application stored in the memory 13, an image data signal and/or an input control signal may be transmitted to the display module 11. The display module 11 may process the received signal and output image information through a display screen.

The power module 14 may include a power supply module such as a power adapter and a battery device, and a power conversion module that converts the power supplied by the power supply module to generate power desired for the operation of the electronic device 1.

At least one of the elements of the electronic device 1 described above may be included in the display device 10 in the embodiments described above. In addition, some of the individual modules functioning as a single module may be included in the display device 10 while some others may be provided separately from the display device 10. In an embodiment, the display device 10 may include the display module 11, and the processor 12, the memory 13 and the power module 14 may be provided as other devices inside the electronic device 1 than the display device 10, for example.

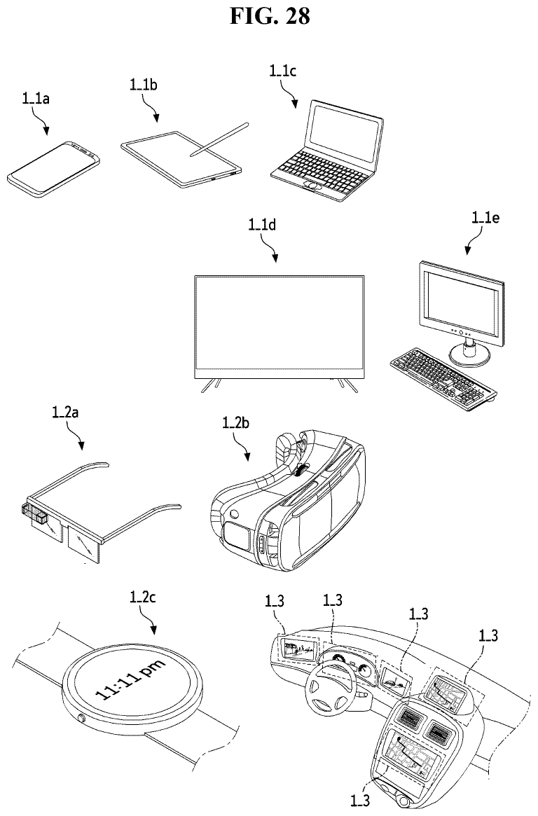

FIG. 28 is a view showing electronic devices according to a variety of embodiments of the disclosure.

Referring to FIG. 28, a variety of electronic devices 1 employing the display devices 10 in the embodiments may include not only image display electronic devices such as a smart phone 1_1a, a tablet PC 1_1b, a laptop computer 1_1c, a television (“TV”) 1_1d and a desktop monitor 1_1e, but also wearable electronic devices including display modules such as smart glasses 1_2a, a head-mounted display 1_2b and a smart watch 1_2c, and electronic devices for vehicles 1_3 including display modules such as a center information display (“CID”) placed on the dashboard, the center fascia and the dashboard of a vehicle, and a room mirror display.

In concluding the detailed description, those skilled in the art will appreciate that many variations and modifications may be made to the preferred embodiments without substantially departing from the principles of the disclosure. Therefore, the disclosed preferred embodiments of the disclosure are used in a generic and descriptive sense only and not for purposes of limitation.

What is claimed is:

1. A display device comprising:
a display panel comprising a folding area and a non-folding area; and
a panel support member placed on the display panel, the panel support member comprising:
a folding portion disposed in the folding area, the folding portion comprising:
a grid pattern in which a plurality of slits and a plurality of bars are arranged alternately; and
a non-folding portion disposed in the non-folding area,
a first surface next to the display panel in a cross-section cut in a thickness direction;
a second surface opposed to the first surface;
a first inner surface connected to the first surface in a slit of the plurality of slits, disposed between the first surface and the second surface, the first inner surface comprising:
a curved surface; and
a second inner surface disposed between the first inner surface and the second surface in the slit,
wherein a point where the first surface and the first inner surface meet is defined as a first point, a point where the second surface and the second inner surface meet is defined as a second point, and a point where the first inner surface and the second inner surface meet is defined as a third point,
wherein the slit has a first width in a direction parallel to the first surface at the first point, a second width in a direction parallel to the second surface at the second point, and a third width, which is a minimum width, in the direction parallel to at least one of the first surface and the second surface at the third point,
wherein the third width is smaller than the first width, and the first width is smaller than the second width,
wherein a first reference point is defined where a straight line extended in a horizontal direction perpendicular to the thickness direction at a point distant from the first point by a first vertical distance in the thickness direction meets the first inner surface, and
wherein a first angle defined by a first tangent touching the first inner surface at the first reference point and the first surface ranges from 15 degrees to 30 degrees when the first vertical distance is 0.5 micrometer.

2. The display device of claim 1, wherein a distance between the first reference point and the first point in the horizontal direction is defined as a first horizontal distance, and wherein the first horizontal distance is two to four times the first vertical distance.

3. The display device of claim 1, wherein a second reference point is defined where a straight line extended in the horizontal direction at a point distant from the second point by a second vertical distance in the thickness direction meets the second inner surface,
wherein a second angle defined by a second tangent touching the second inner surface at the second reference point and the second surface is greater than the first angle, and
wherein the second vertical distance is equal to the first vertical distance.

4. The display device of claim 1, wherein a first contact point disposed on the first inner surface and next to the first point, and a second contact point next to the third point are defined,
wherein a distance between the first point and the first contact point on the first inner surface is equal to a distance between the third point and the second contact point on the first inner surface, and
wherein a first radius of a first inscribed circle touching the first inner surface at the first contact point is larger than a second radius of a second inscribed circle touching the first inner surface at the second contact point.

5. The display device of claim 4, wherein an arbitrary third contact point disposed on the second inner surface is defined, and
wherein a third radius of a third inscribed circle touching the second inner surface at the third contact point is greater than the first radius and the second radius.

6. The display device of claim 1, wherein a distance by which the third point is spaced apart from the first surface in the thickness direction is greater than 0.2 times and less than 0.4 times the thickness of the panel support member.

7. The display device of claim 6, wherein the thickness of the panel support member ranges from 80 micrometers to 150 micrometers.

8. The display device of claim 1, wherein the first width ranges from 20 micrometers to 80 micrometers, the second width ranges from 40 micrometers to 150 micrometers, and the third width ranges from 10 micrometers to 40 micrometers.

9. The display device of claim 1, wherein the second inner surface comprises a curved surface next to the first inner surface and a flat surface next to the second surface.

10. The display device of claim 1, wherein the panel support member includes glass.

11. The display device of claim 1, further comprising: a filling member comprising a first portion disposed in the slit, and a second portion overlapping the folding portion on the second surface.

12. The display device of claim 11, wherein the filling member further comprises: the filling member comprises a third portion overlapping the non-folding portion on the second surface, and a fourth portion disposed on a side surface of the panel support member.

13. A display device comprising:
a display panel comprising:
a folding area;
a non-folding area; and
a panel support member placed on the display panel, the panel support member comprising:
a folding portion disposed in the folding area, the folding portion comprising:
a grid pattern in which a plurality of slits and a plurality of bars are arranged alternately;
a non-folding portion disposed in the non-folding area;
a first surface next to the display panel in a cross-section cut in a thickness direction;
a second surface opposed to the first surface;
a first inner surface connected to the first surface in a slit of the plurality of slits, disposed between the first surface and the second surface, the first inner surface comprising:
a curved surface; and
a second inner surface disposed between the first inner surface and the second surface in the slit,
wherein a point where the first surface and the first inner surface meet is defined as a first point, a point where the second surface and the second inner surface meet is defined as a second point, and a point where the first inner surface and the second inner surface meet is defined as a third point,
wherein the slit has a first width in a direction parallel to the first surface at the first point, a second width in a direction parallel to the second surface at the second point, and a third width, which is a minimum width, in the direction parallel to at least one of the first surface and the second surface at the third point,
wherein the third width is smaller than the first width, and the first width is smaller than the second width, and
wherein the panel support member has a shape optimization index Q of 0.35 or greater defined by a following equation:
$$Ω = 100 \cdot \frac{D}{w 1 ( w 1 - w 3 )}$$
wherein w1 denotes the first width, w3 denotes the third width, and D denotes the distance by which the third point is spaced apart from the first surface in the thickness direction.

14. The display device of claim 13, wherein the w3 ranges from 10 micrometers to 40 micrometers, the w1 ranges from 20 micrometers to 80 micrometers, and the D ranges from 20 micrometers to 50 micrometers.

15. A method for fabricating a display device, the method comprising:
forming a sketch line by irradiating a glass plate with a laser;
bringing a first etchant into contact with at least a surface of the glass plate on which the sketch line is formed to define a slit along the sketch line;
immersing the glass plate in which the slit is defined in a second etchant to perform first healing;
chemically strengthening the glass plate after the first healing by immersing it in molten salt;
immersing the chemically strengthened glass plate in a third etchant to perform second healing; and
filling the slit of the glass plate after the second healing with a resin.

16. The method of claim 15, wherein an etching rate of the glass plate by the second etchant is slower than an etching rate of the glass plate by the first etchant.

17. The method of claim 15, wherein the second etchant and the third etchant include a same material as each other.

18. The method of claim 15, wherein the first etchant and the second etchant each include ammonium ions and bifluoride ions,
wherein a ratio of ammonium ions to total ions in the first etchant is smaller than a ratio of ammonium ions to total ions in the second etchant, and
wherein a ratio of bifluoride ions to total ions in the first etchant is larger than a ratio of bifluoride ions to total ions in the second etchant.

19. The method of claim 15, wherein the slit comprises a first portion next to an upper surface of the glass plate, a second portion next to a lower surface of the glass plate, and a third portion between the first portion and the second portion in a thickness direction of the glass plate, and
wherein a width of the third portion is smaller than a width of the first portion, and the width of the first portion is smaller than a width of the second portion.

20. An electronic device comprising:
a display device for displaying an image, the display device comprising:
a display panel comprising:
a folding area; and
a non-folding area; and
a panel support member placed on the display panel, the panel support member comprising:
a folding portion disposed in the folding area, the folding portion comprising:
a grid pattern in which a plurality of slits and a plurality of bars are arranged alternately; and
a non-folding portion disposed in the non-folding area
a first surface next to the display panel in a cross-section cut in a thickness direction;
a second surface opposed to the first surface;
a first inner surface connected to the first surface in a slit of the plurality of slits, disposed between the first surface and the second surface, the first inner surface comprising:
a curved surface; and
a second inner surface disposed between the first inner surface and the second surface in the slit;
a processor which provides an image driving signal to the display device; and
a power module which supplies power to the display device and the processor,
wherein a point where the first surface and the first inner surface meet is defined as a first point, a point where the second surface and the second inner surface meet is defined as a second point, and a point where the first inner surface and the second inner surface meet is defined as a third point,
wherein the slit has a first width in a direction parallel to the first surface at the first point, a second width in a direction parallel to the second surface at the second point, and a third width, which is a minimum width, in the direction parallel to at least one of the first surface and the second surface at the third point,
wherein the third width is smaller than the first width, and the first width is smaller than the second width,
wherein a first reference point is defined where a straight line extended in a horizontal direction perpendicular to the thickness direction at a point distant from the first point by a first vertical distance in the thickness direction meets the first inner surface, and
wherein a first angle defined by a first tangent touching the first inner surface at the first reference point and the first surface ranges from 15 degrees to 30 degrees when the first vertical distance is 0.5 micrometer.
